(19) United States
(12) Patent Application Publication
(10) Pub. No.: US 2026/0020383 A1
(43) Pub. Date: Jan. 15, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Mi Hyang SHEEN, Yongin-si (KR); Tae Kyu KIM, Yongin-si (KR); Hyun Won KIM, Yongin-si (KR); Jae Han LEE, Yongin-si (KR)

(21) Appl. No.: 19/261,933

(22) Filed: Jul. 7, 2025

(30) Foreign Application Priority Data
Jul. 10, 2024 (KR) 10-2024-0090896

(51) Int. Cl. H10H 20/819; H10H 29/01; H10H 29/49

(52) U.S. Cl. CPC H10H 20/819; H10H 29/012; H10H 29/49

(57) ABSTRACT

A display device, a method for manufacturing the same, and an electronic device are provided. A display device includes: a substrate; a pixel electrode and a common electrode spaced from each other on the substrate; a light emitting element on the pixel electrode and the common electrode, and including a first contact electrode and a second contact electrode, wherein the light emitting element further includes: a first element rod having a tapered shape, and including a first semiconductor layer doped with a first conductive dopant and an active layer; and a second element rod on the first element rod and including a second semiconductor layer doped with a second conductive dopant and having a greater inclination angle than the first element rod.

### CROSS-REFERENCE TO RELATED APPLICATION

The present application claims priority to and the benefit of Korean Patent Application No. 10-2024-0090896, filed on Jul. 10, 2024, in the Korean Intellectual Property Office, the entire disclosure of which is incorporated by reference herein.

### BACKGROUND

### 1. Field

The present disclosure relates to a display device, a method for manufacturing the same and an electronic device including the display device.

### 2. Description of the Related Art

As the information society develops, the demand for display devices for

displaying images is increasing in various forms. The display device may be a flat panel display device such as a liquid crystal display, a field emission display, or a light emitting display, and/or the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has the advantage of having less deterioration issues and a longer lifespan compared to organic light emitting diode (OLED) elements.

### SUMMARY

Aspects and features of embodiments of the present disclosure are to provide a display device and a manufacturing method thereof that may increase light extraction efficiency and reduce power consumption.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes: a substrate; a pixel electrode and a common electrode spaced from each other on the substrate; a light emitting element on the pixel electrode and the common electrode, and including a first contact electrode and a second contact electrode, wherein the light emitting element further includes: a first element rod having a tapered shape (e.g., a regular tapered shape), and including a first semiconductor layer doped with a first conductive dopant and an active layer; and a second element rod on the first element rod and including a second semiconductor layer doped with a second conductive dopant and having a greater inclination angle than the first element rod.

In one or more embodiments, a first inclination angle between an inner surface of the first element rod and one surface of the first semiconductor layer is in a range of 20° to 65°, wherein a second inclination angle between an outer surface of the second element rod and an outer surface of the first element rod is in a range of 110° to 155°.

In one or more embodiments, the first element rod has a width that becomes narrower toward the top on the substrate, and the second element rod has a same width at the top and bottom.

In one or more embodiments, the second element rod further includes an undoped semiconductor on the second semiconductor layer.

In one or more embodiments, the undoped semiconductor has a light extraction pattern.

In one or more embodiments, the display device further including an organic layer on a lower surface of the light emitting element on the pixel electrode and the common electrode; and a first connection electrode connecting the pixel electrode and the first contact electrode and a second connection electrode connecting the common electrode and the second contact electrode.

In one or more embodiments, the display device further including a first connection electrode between the first contact electrode and the pixel electrode, and a second connection electrode between the second contact electrode and the common electrode.

In one or more embodiments, the light emitting element further includes a conductive layer on a bottom surface of the first semiconductor layer, wherein a protective layer around the conductive layer and the first semiconductor layer, the active layer, and the second semiconductor layer, wherein the first contact electrode is on the protective layer and is connected to the conductive layer that is exposed and not covered by the protective layer, wherein the second contact electrode is on the protective layer and is located in a hole penetrating the conductive layer, the first semiconductor layer, and the active layer.

In one or more embodiments, the display device further including a partition wall around the light emitting element; and a reflective layer on a side surface of the partition wall and at a space defined by the partition wall, the reflective layer being not in contact with the pixel electrode and the common electrode.

In one or more embodiments, the display device further including a wavelength conversion layer at the space defined by the partition wall.

In one or more embodiments, a display device including: a substrate; a pixel electrode on the substrate; a light emitting element on the pixel electrode, and including a contact electrode; and a common electrode on the light emitting element, wherein the light emitting element further including: a first element rod having a tapered shape, and including a first semiconductor layer doped with a first conductive dopant and an active layer; and a second element rod on the first element rod, and including a second semiconductor layer doped with a second conductive dopant and having a greater inclination angle than the first element rod.

In one or more embodiments, a first inclination angle between an inner surface of the first element rod and one surface of the first semiconductor layer is in a range of 20° to 65°, and wherein a second inclination angle between an outer surface of the second element rod and an outer surface of the first element rod is in a range of 110° to 155°.

In one or more embodiments, the first element rod has a width that becomes narrower toward the top on the substrate, and the second element rod has a same width at the top and bottom.

In one or more embodiments, the display device further including an organic layer between the pixel electrode and the light emitting element; and a connection electrode connecting the pixel electrode and the contact electrode.

In one or more embodiments, the display device further including a connection electrode between the contact electrode and the pixel electrode.

In one or more embodiments, wherein the light emitting element further includes: a conductive layer on a bottom surface of the first semiconductor layer; and a protective film on side surfaces of the conductive layer and side surfaces of the first semiconductor layer and the active layer, wherein the contact electrode is on the protective film and is connected to the conductive layer exposed without being covered by the protective film.

In one or more embodiments, the display device further including a partition wall around the light emitting element; and a wavelength conversion layer at a space defined by the partition wall.

In one or more embodiments, a method for manufacturing a display device including: forming a light emitting element; and transferring the light emitting element onto a first substrate, wherein the forming the light emitting element includes: forming an undoped semiconductor, a second semiconductor layer, an active layer, a first semiconductor layer, and a conductive layer on a second substrate; forming a double mask on the first semiconductor layer and performing a first etching; performing a second etching according to an etching method different from the first etching, and continuing the second etching until an inner surface of the first semiconductor layer and the active layer has a first inclination angle and an outer surface of the second semiconductor layer and an outer surface of the first semiconductor layer and the active layer have a second inclination angle; forming a groove penetrating the conductive layer, the first semiconductor layer, and the active layer to expose the second semiconductor layer; forming a protective layer around the conductive layer, the first semiconductor layer, the active layer, the second semiconductor layer, and the undoped semiconductor; and forming a first contact electrode in contact with the conductive layer on the protective layer, and a second contact electrode in contact with the second semiconductor layer exposed by the groove.

In one or more embodiments, the first inclination angle is in a range of 20° to 65°, and wherein the second inclination angle is in a range of 110° to 155°.

In one or more embodiments, the first etching is dry etching, and the second etching is wet etching.

In one or more embodiments, an electronic device including: a display device for displaying an image, wherein the display device includes: a substrate; a pixel electrode and a common electrode spaced from each other on the substrate; a light emitting element on the pixel electrode and the common electrode, and including a first contact electrode and a second contact electrode, wherein the light emitting element further including: a first element rod having a tapered shape, and including a first semiconductor layer doped with a first conductive dopant and an active layer; and a second element rod on the first element rod and including a second semiconductor layer doped with a second conductive dopant and having a greater inclination angle than the first element rod.

According to the display device and its manufacturing method according to the embodiments, the amount of light emitted toward the lower side of the light emitting element may be reduced, thereby improving the reflectivity and light extraction effect. Accordingly, the panel brightness may be increased, and the power consumption for the same brightness may be reduced.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout drawing illustrating pixels of a display area according to one or more embodiments.

FIG. 6 is a cross-sectional view illustrating one example of a cross-section of a display panel corresponding to the line I-I′ in FIG. 5.

FIG. 7 is a cross-sectional view illustrating one example of an area A1 of FIG. 6 in detail.

FIG. 8 is a drawing illustrating the direction of travel of light emitted from the light emitting element of FIG. 7.

FIG. 9 is a cross-sectional view illustrating another example of the area A1 of FIG. 6 in detail.

FIG. 10 is a cross-sectional view illustrating an example of a cross-section of a display panel corresponding to the line I-I′ of FIG. 5.

FIG. 11 is a cross-sectional view illustrating another example of an area A2 of FIG. 6 in detail.

FIG. 12 is a layout drawing illustrating pixels of a display area according to one or more embodiments.

FIG. 13 is a cross-sectional drawing illustrating an example of a cross-section of a display panel corresponding to the line I1-I1′ of FIG. 12.

FIG. 14 is a cross-sectional drawing illustrating an example of the area A2 of FIG. 13 in detail.

FIG. 15 is a cross-sectional drawing illustrating another example of the area A2 of FIG. 13 in detail.

FIG. 16 is a flowchart illustrating a method of manufacturing a display device according to one or more embodiments.

FIGS. 17-35 are example drawings to illustrate a method of manufacturing a display device according to one or more embodiments.

FIG. 36 is an example view of a smart watch including a display device according to one or more embodiments.

FIGS. 37 and 38 are example views of a virtual reality (VR) device including a display device according to one or more embodiments.

FIG. 39 is an example view of a VR device including a display device according to one or more embodiments.

FIG. 40 is an example view illustrating a vehicle instrument cluster and center fascia including display devices according to one or more embodiments.

FIG. 41 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

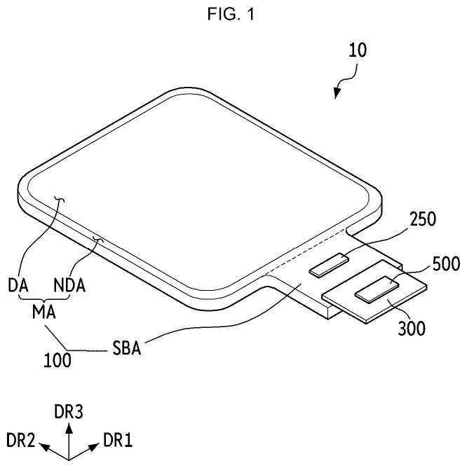

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and/or ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit board 300, and a power supply unit (e.g., a power supply circuit) 500.

The display panel 100 may be formed as (or may have) a rectangular shaped plane having a short side in the first direction DR1 and a long side in the second direction DR2 that intersects the first direction DR1. A corner where the short side in the first direction DR1 and the long side in the second direction DR2 meet may be rounded to have (or may have) a suitable curvature (e.g., a predetermined curvature) or may be formed at a right angle. The planar shape of the display panel 100 is not limited to a rectangle, but may be formed in (or may have) other polygonal, circular, or oval shapes. The display panel 100 may be formed flat but is not limited thereto. In one example, the display panel 100 may include curved portions with a constant curvature or a changing curvature at left and/or right ends. In addition, the display panel 100 may be flexibly formed to be bent, curved, bent, folded, and/or rolled.

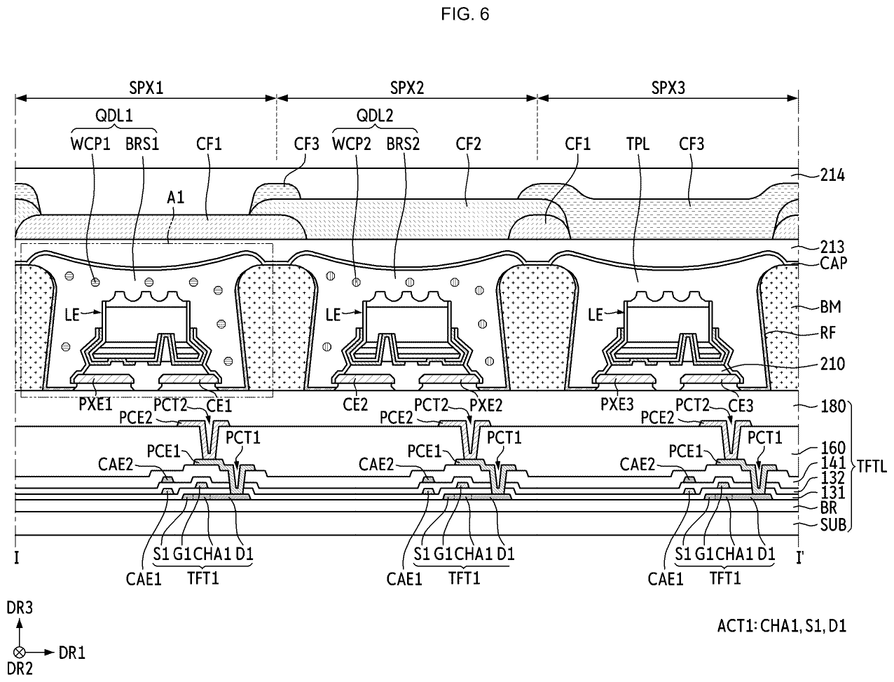

The substrate SUB (e.g., see FIG. 6) of the display panel 100 may include a main area MA and a sub area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. In one or more embodiments, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip on film (COF).

The power supply unit 500 may generate a plurality of panel driving voltages according to an external power supply voltage. The power supply unit 500 may be formed as an integrated circuit (IC) and attached to the circuit board 300 using a COF method.

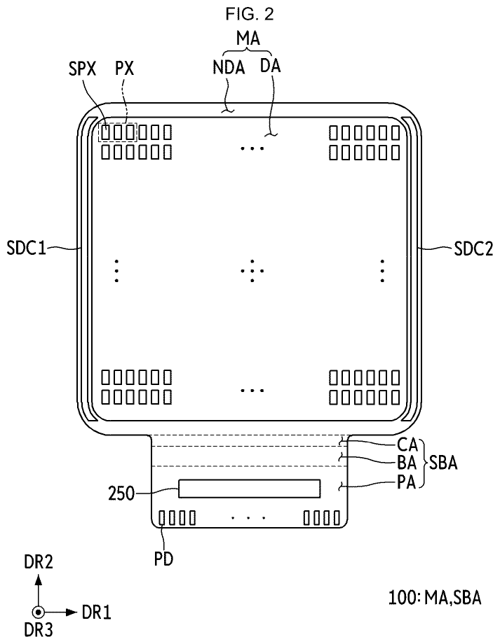

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to surround the display area DA. The non-display area NDA may be an edge area of the display panel 100.

A first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100. However, the present disclosure is not limited thereto.

Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

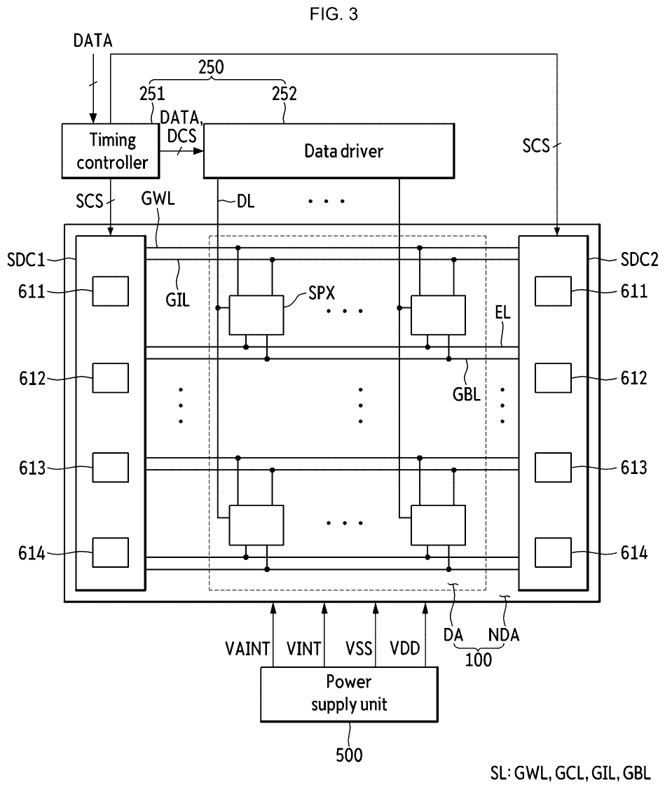

FIG. 3 is a block drawing illustrating a display device according to one or more embodiments.

Referring to FIG. 3, the display area DA includes a plurality of pixels PX including a plurality of sub-pixels SPX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and be disposed along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines GCL.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light-emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emitting signal output portion 614. Each of the write scan signal output portion 611, the initialization scan signal output portion 612, the bias scan signal output portion 613, and the light emitting signal output portion 614 may receive a scan timing control signal SCS from a timing controller 251. The write scan signal output portion 611 may generate write scan signals according to the scan timing control signal SCS of the a timing controller 251 and sequentially output them to the write scan lines GWL. The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines GBL. The light emitting signal output portion 614 may generate light emitting control signals according to the scan timing control signal SCS and sequentially output them to the emission control lines EL.

The display driving circuit 250 includes a timing controller (e.g., a timing control circuit) 251 and a data driving circuit 252.

The data driving circuit 252 may receive digital video data DATA and a data timing control signal DCS from the timing controller 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing controller 251 may receive digital video data and timing signals from an external source. The timing controller 251 may generate the scan timing control signal SCS and the data timing control signal DCS to control the display panel 100 according to timing signals. The timing controller 251 may output the scan timing control signal SCS to the first scan driving unit SDC1 and the second scan driving unit SDC2. The timing controller 251 may output digital video data DATA and a data timing control signal DCS to the data driving circuit 252.

The power supply unit 500 may generate a plurality of panel driving voltages according to an external power supply voltage. For example, the power supply unit 500 may generate and supply a first driving voltage VDD, a second driving voltage VSS, a third driving voltage VINT, and a fourth driving voltage VAINT to the display panel 100.

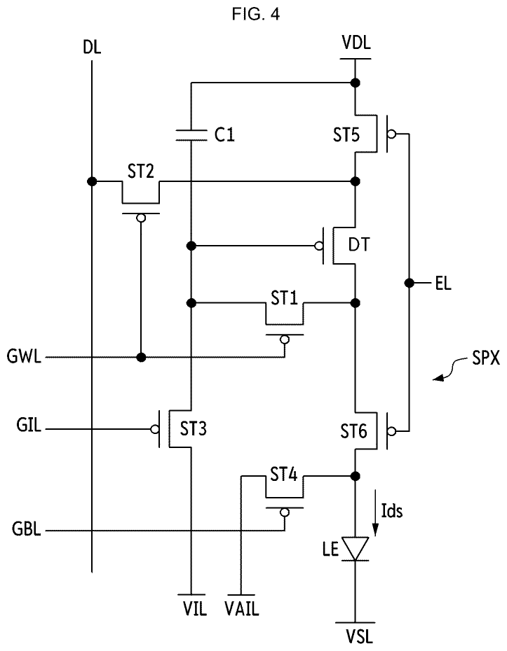

FIG. 4 is an equivalent circuit drawing illustrating a sub-pixel according to one or more embodiments.

Referring to FIG. 4, the sub-pixel SPX according to one or more embodiments may be connected to scan lines GWL, GIL, and GBL, an emission line EL, and a data line DL. For example, the sub-pixel SPX may be connected to the write scan line GWL, the initialization scan line GIL, the bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit PXC.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power voltage VSS is applied.

The capacitor C1 is formed between the gate electrode of the driving transistor DT and the first power supply line VDL to which the first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, the gate electrode of the fourth transistor ST4 may be connected to the bias scan line GBL, and the gate electrodes of the fifth and sixth transistors ST5 and ST6 may be connected to the emission line EL. Because the first to sixth transistors ST1, ST2, ST3, ST4, ST5, and ST6 are formed as p-type MOSFET, they may be turned on when a scan signal and an emission signal with a gate low voltage are applied to the initialization scan line GIL, the write scan line GWL, the bias scan line GBL, and the emission line EL, respectively. One electrode of the third transistor ST3 and one electrode of the fourth transistor ST4 may be connected to the initialization voltage lines VIL and VAIL, respectively.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. The active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor.

In this case, because the first transistor ST1 and the third transistor ST3 are formed as n-type MOSFET, the first transistor ST1 may be turned on when a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission signal of the gate low voltage are applied.

Alternatively, the fourth transistor ST4 may be formed of an n-type MOSFET, so that each active layer of the fourth transistor ST4 may be formed of an oxide semiconductor. When the fourth transistor ST4 is formed of an n-type MOSFET, it may be turned on when a scan signal of the gate high voltage is applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

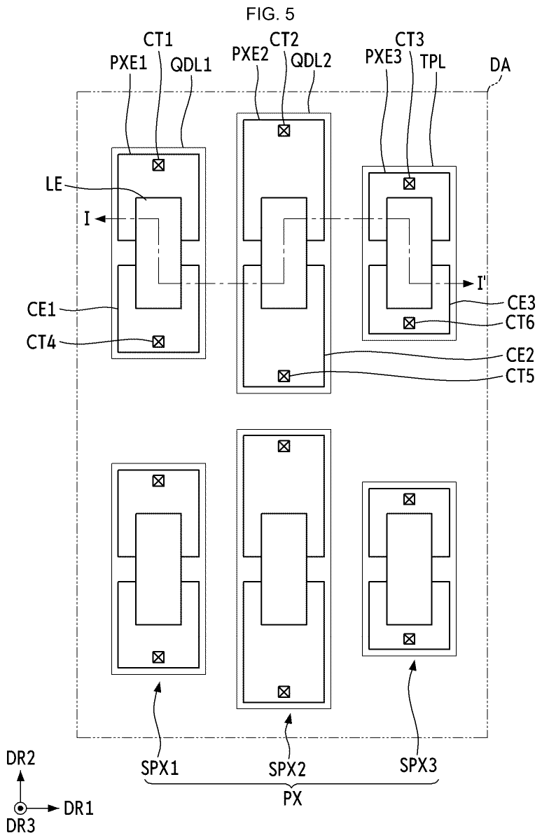

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be disposed along the first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a plurality of light emitting elements LE, a first common electrode CE1, and a first light conversion layer QDL1. The second sub-pixel SPX2 includes a second pixel electrode PXE2, the plurality of light emitting elements LE, a second common electrode CE2, and the second light conversion layer QDL2. The third sub-pixel SPX3 includes a third pixel electrode PXE3, a plurality of light emitting elements LE, a third common electrode CE3, and a light transmission layer TPL.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. Each of the pixel electrodes PXE1, PXE2, and PXE3 and the common electrodes CE1, CE2, and CE3 may have a rectangular planar shape, but the present disclosure is not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits light of the light emitting element LE as it is, the first light conversion layer QDL1 need to convert the light. Therefore, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which the second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrodes CE1, CE2, and CE3. Each of the plurality of light emitting elements LE may have a rectangular planar shape, but the present disclosure is not limited thereto. For example, each of the plurality of light emitting elements LE may have a circular planar shape.

The first light conversion layer QDL1 may completely overlap the plurality of light emitting elements LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third sub-pixel SPX3. The light transmission layer TPL may transmit incident light as it is. For example, the light transmission layer TPL may directly transmit the third light emitted from the plurality of light emitting elements LE of the third sub-pixel SPX3.

When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

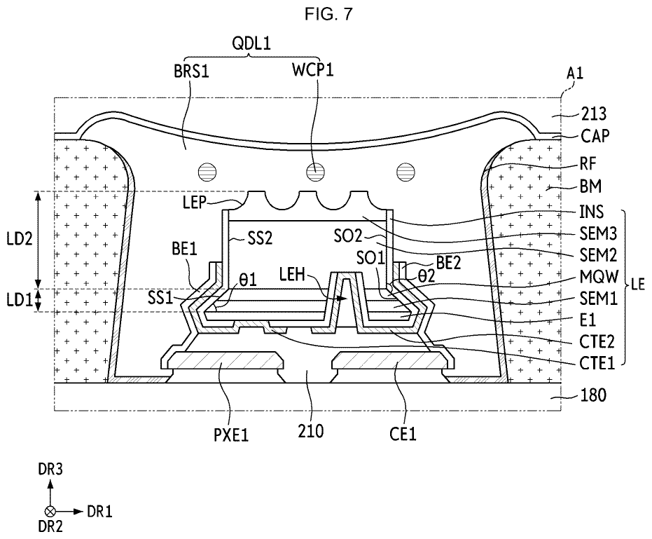

FIG. 6 is a cross-sectional view illustrating one example of a cross-section of a display panel corresponding to the line I-I′ in FIG. 5. FIG. 7 is a cross-sectional view illustrating one example of an area A1 of FIG. 6 in detail.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL and the light emitting layer of the light emitting element layer from moisture penetrating through the substrate SUB, which is vulnerable to moisture penetration. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and the barrier film BR.

A first gate metal layer may be disposed on the first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be spaced (e.g., spaced apart) from each other, but the first gate electrode G1 and the first capacitor electrode CAE1 may be connected to each other.

A second gate insulating film 132 may be disposed on the first gate electrode G1 of the thin film transistor TFT1, the first capacitor electrode CAE1, and the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 and first interlayer insulating film 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be disposed on the second source connection electrode PCE2 and the first planarization organic film 160.

The barrier film BR, the first gate insulating film 131, the second gate insulating film 132, the third gate insulating film 133, and the interlayer insulating film 141 may be formed from an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be disposed on the second planarization organic film 180. The light emitting element layer may include pixel electrodes PXE1, PXE2, PXE3, light emitting elements LE, common electrode CE, and organic layer 210.

A pixel electrode layer including the pixel electrodes PXE1, PXE2, and PXE3 and the common electrodes CE1, CE2, and CE3 may be disposed on the second planarization organic film 180.

Each of the first pixel electrode PXE1, the second pixel electrode PXE2, and the third pixel electrode PXE3 may be connected to the second source connection electrode PCE2 through a connection hole (CT1, CT2, and CT3 in FIG. 5) penetrating the second planarization organic film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through the common connection hole (CT4, CT5, and CT6 in FIG. 5). The first common electrode CE1 may be connected to the second power supply line (VSL in FIG. 4) through the first common connection hole CT4. The second common electrode CE2 may be connected to the second power supply line (VSL in FIG. 4) through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

An organic layer 210 may be disposed on each pixel electrode layer. For example, the organic layer 210 may cover at least a portion of the pixel electrodes PXE1, PXE2, and PXE3 and at least a portion of the common electrodes CE1, CE2, and CE3.

The organic layer 210 serves to temporarily fix or adhere the upper member (e.g., light emitting element LE). For example, the organic layer 210 may be a film for temporarily adhering an upper member (e.g., light emitting element LE) to each of the pixel electrodes PXE1, PXE2, and PXE3 and the common electrodes CE1, CE2, and CE3. To facilitate temporary adhesion, the thickness of the organic layer 210 may be greater than the thickness of each of the pixel electrodes PXE1, PXE2, and PXE3 and the common electrodes CE1, CE2, and CE3 and greater than the thickness of the contact electrode CTE (CTE1, CTE2). The thickness of the organic layer 210 may be about 2 μm but is not limited thereto.

In one or more embodiments, the organic layer 210 may be disposed in an island pattern shape in each sub-pixel SPX1, SPX2, and SPX3. For example, the organic layer 210 disposed in each sub-pixel SPX1, SPX2, and SPX3 may be spaced (e.g., spaced apart) from the organic layer 210 disposed in the adjacent sub-pixel SPX1, SPX2, and SPX3.

The organic layer 210 may be a photosensitive organic film, such as photoresist. Alternatively, the organic layer 210 may be formed from an acrylic resin, an epoxy resin, a phenolic resin, a polyamide resin, a polyimide resin, and/or the like.

A plurality of light emitting elements LE may be disposed on the organic layer 210. FIGS. 6 and 7 illustrate that the light emitting element LE is a flip-type micro LED. The flip-type micro LED refers to an LED in which contact electrodes CTE1 and CTE2 are formed on (e.g., located at) one side (e.g., the bottom side) of the light emitting element LE.

Each of the plurality of light emitting elements LE may be formed of an inorganic material such as gallium nitride (GaN).

Each of the plurality of light emitting elements LE may be formed by growing on a semiconductor substrate such as a silicon substrate and/or sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 through an electrostatic method using an electrostatic head and/or a stamp method using an elastic polymeric material such as PDMS (polydimethylsiloane) or silicone as a transfer substrate.

In one or more embodiments, a reflective film may be disposed on the top surface of the pixel electrode PXE1 and the common electrode CE1.

The reflective film may reflect light proceeding downward from the light emitting element LE and emit light to the top surface of the light emitting element LE. Therefore, light loss of the light emitting element LE may be reduced, so that the light efficiency of the light emitting element LE may be increased.

The reflective film may be formed as a single layer of a highly reflective metal, or may be formed as a multilayer, such as titanium (Ti)/aluminum (Al)/titanium (Ti) and/or ITO/aluminum (Al)/ITO.

The light emitting element LE may include a conductive layer E1, a first semiconductor layer SEM1, an active layer MQW, a second semiconductor layer SEM2, a third semiconductor layer SEM3, a first contact electrode CTE1, a second contact electrode CTE2, and a protective film INS.

The conductive layer E1 may be disposed on the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may include a semiconductor material layer doped with a first conductive dopant, such as magnesium (Mg), zinc (Zn), calcium (Ca), strontium (Sr), barium (Ba), and/or the like, for example gallium nitride (GaN).

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt % to 20 wt %.

The second semiconductor layer SEM2 may be disposed on the active layer MQW. The second semiconductor layer SEM2 may be a semiconductor material layer doped with a second conductivity type dopant such as silicon (Si), germanium (Ge), tin (Sn), etc., for example, gallium nitride (GaN).

The third semiconductor layer SEM3 may be disposed on the second semiconductor layer SEM2.

The third semiconductor layer SEM3 is a layer of semiconductor material in which the n-type dopant is below a suitable threshold (e.g., a predetermined threshold), which may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the n-type dopant is below a suitable threshold (e.g., a predetermined threshold).

The top surface of the third semiconductor layer SEM3 may have a light extraction pattern LEP.

The light extraction patterns LEP may be patterns for increasing the efficiency of light emitted from the upper surface of the light emitting element LE. The light extraction patterns LEP may be concave patterns formed in (or having) a hemispherical or a semi-elliptical shape. The light extraction patterns LEP may be concave patterns having a semicircular or semi-elliptical cross-sectional shape.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The light emitting element LE may be divided into a conductive layer E1, a first element rod LD1, a second element rod LD2, a first contact electrode CTE1, and a second contact electrode CTE2.

The first element rod LD1 may be disposed closer to the second planarization organic film 180 than the second element rod LD2. The first element rod LD1 has a tapered shape with a width that decreases toward the top. The first element rod LD1 may include the first semiconductor layer SEM1 and the active layer MQW. Therefore, in the first element rod LD1, the width of the first semiconductor layer SEM1 is wider than the width of the active layer MQW.

When the first element rod LD1 has a tapered shape, the light extraction effect may be improved compared to the reverse tapered shape.

For example, for convenience of explanation, the inner side of the first element rod LD1 is referred to as the first inner side SS1 and the inner side of the second element rod LD2 is referred to as the second inner side SS2. The outer side of the first element rod LD1 is referred to as the first outer side SO1 and the outer side of the second element rod LD2 is referred to as the second outer side SO2.

The first inclination angle 01 formed between the first inner side SS1 of the first element rod LD1 and one surface of the first semiconductor layer SEM1 may be in a range of about 20° to 65°.

The second inclination angle 02 formed between the second outer side SO2 of the second element rod LD2 and the first outer side SO1 of the first element rod LD1 may be in a range of about 110° to 155°.

The second element rod LD2 is disposed on the first element rod LD1 and may include a side surface that is relatively vertical compared to the first element rod LD1. The second element rod LD2 may have a width of a top surface and a width of a bottom surface that are substantially the same. For example, the second semiconductor layer SEM2 may have a cross-sectional shape that is substantially the same as a rectangle or square. The width of the third semiconductor layer SEM3 of the second element rod LD2 is narrower than the width of the active layer MQW.

The second element rod LD2 may secure the volume of the second semiconductor layer SEM2 by forming a side surface that is vertical compared to the tapered shape and may increase or maximize the injection of electron carriers into the active layer MQW. For example, when the second element rod LD2 is formed in (or has) the same tapered shape as the first element rod LD1, the width of the top surface of the second semiconductor layer SEM2 becomes narrower than the width of the bottom surface, so that the volume of the second semiconductor layer SEM2 decreases.

The protective film INS may be a film for protecting the bottom surface and the side surface of the light emitting element LE. The protective film INS may be disposed on the bottom surface and the side surface of the conductive layer E1 and the side surfaces of the plurality of semiconductor layers SEM1, MQW, SEM2, and SEM3. The protective film INS may be formed of an inorganic film, such as silicon nitride (SiNₓ), silicon oxide (SiON), silicon oxide (SiOₓ), titanium oxide (TiOₓ), and/or aluminum oxide (AlOₓ). The protective film INS is preferably disposed from one end to the other end of the side surface of the light emitting element LE but may be disposed slightly apart from one end due to process errors.

A hole LEH may be formed to expose (or may expose) a second semiconductor layer SEM2 by penetrating the conductive layer E1, the first semiconductor layer SEM1, and the active layer MQW of the light emitting element LE. The hole LEH may have a tapered shape, but the embodiment of the present disclosure is not limited thereto. For example, the hole LEH may have a polygonal, circular, and elliptical planar shape, such as a square.

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be disposed on at least one side of the semiconductor layers SEM1, MQW, SEM2, and SEM3 and at least one side and the bottom surface of the conductive layer E1. The first contact electrode CTE1 may be disposed on the bottom surface of the conductive layer E1 that is exposed and not covered by the protective film INS. Therefore, the first contact electrode CTE1 may be electrically connected to the conductive layer E1.

The second contact electrode CTE2 may be disposed on at least one side of the semiconductor layers SEM1, MQW, SEM2, and SEM3 and at least one side and the bottom surface of the conductive layer E1. At this time, the first contact electrode CTE1 may be disposed on the first side of the semiconductor layers SEM1, MQW, SEM2, and SEM3 and the first side of the conductive layer E1, while the second contact electrode CTE2 may be disposed on the second side of the semiconductor layers SEM1, MQW, SEM2, and SEM3 and the second side of the conductive layer E1.

The second contact electrode CTE2 may be disposed on the protective layer INS disposed in the hole LEH and the second semiconductor layer SEM2 exposed without being covered by the protective layer INS in the hole LEH. Therefore, the second contact electrode CTE2 may be electrically connected to the second semiconductor layer SEM2 in the hole LEH.

The first contact electrode CTE1 and the second contact electrode CTE2 may be disposed on at least a portion of the side surfaces of the plurality of semiconductor layers SEM1, MQW, and SEM2. The first contact electrode CTE1 and the second contact electrode CTE2 are spaced (e.g., spaced apart) from the top surface of the light emitting element LE in the third direction DR3. For example, from among the sides of the plurality of semiconductor layers SEM1, MQW, SEM2, and SEM3, at least an area adjacent to the top surface of the third semiconductor layer SEM3 may be exposed without being covered by the first contact electrode CTE1 and the second contact electrode CTE2.

The first contact electrode CTE1 and the second contact electrode CTE2 may be formed lower than (e.g., located below) at least one end of the protective film INS. The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be disposed on three sides of the plurality of semiconductor layers SEM1, MQW, SEM2, and SEM3. For example, when the plurality of semiconductor layers SEM1, MQW, SEM2, and SEM3 include the first to fourth sides, the first contact electrode CTE1 may be disposed on the first side, the second side, and the third side, and the second contact electrode CTE2 may be disposed on the second side, the third side, and the fourth side.

The connection electrodes BE1 and BE2 electrically connect the light emitting element LE and the pixel electrode layer.

In one or more embodiments, the first connection electrode BE1 connects the first contact electrode CTE1 of the light emitting element LE and the pixel electrode PXE1, PXE2, and PXE3.

The first connection electrode BE1 may be disposed on the first contact electrode CTE1 disposed on the side surface of the plurality of semiconductor layers SEM1, MQW, SEM2, may extend along the organic layer 210, and may be disposed on the pixel electrode PXE1, PXE2, and PXE3. Accordingly, the first connection electrode BE1 may connect the conductive layer E1 of the light emitting element LE and the pixel electrode PXE1, PXE2, and PXE3.

The second connection electrode BE2 connects the second contact electrode CTE2 of the light emitting element LE and the common electrode CE1, CE2, and CE3. The second connection electrode BE2 may be disposed on the second contact electrode CTE2 disposed on the side surface of the plurality of semiconductor layers SEM1, MQW, SEM2, may extend along the organic layer 210, and may be disposed on the common electrode CE1, CE2, and CE3. Accordingly, the second connection electrode BE2 may connect the second semiconductor layer SEM2 of the light emitting element LE and the common electrode CE1, CE2, and CE3.

The first connection electrode BE1 and the second connection electrode BE2 may be spaced (e.g., spaced apart) from the top surface of the semiconductor layers SEM1, MQW, SEM2, and SEM3 in the third direction DR3. The first connection electrode BE1 and the second connection electrode BE2 may be formed lower than (e.g., located below) at least one end of the first contact electrode CTE1 and the second contact electrode CTE2. For example, the distance between the first connection electrode BE1 and the top surfaces of the plurality of semiconductor layers SEM1, MQW, SEM2, and SEM3 may be greater than the distance between the first contact electrode CTE1 and the top surfaces of the plurality of semiconductor layers SEM1, MQW, SEM2, and SEM3, and the distance between the second connection electrode BE2 and the top surfaces of the plurality of semiconductor layers SEM1, MQW, SEM2, and SEM3 may be greater than the distance between the second contact electrode CTE2 and the top surfaces of the plurality of semiconductor layers SEM1, MQW, SEM2, and SEM3. However, in one or more embodiments, as shown in FIG. 7, the first connection electrode BE1 and the second connection electrode BE2 may be formed at (e.g., may be located at) a same distance from the top surfaces of the plurality of semiconductor layers SEM1, MQW, SEM2, and SEM3 as the first contact electrode CTE1 and the second contact electrode CTE2 are.

The thicknesses of the first connection electrode BE1 and the second connection electrode BE2 may each be about 1000 Å but are not limited thereto.

The first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Alternatively, the second connection electrode BE2 may be made of a transparent conductive material (TCO), such as indium tin oxide (ITO) and/or indium zinc oxide (IZO).

A partition wall BM may be further disposed on the second planarization organic film 180 to compartmentalize each sub-pixel SPX1, SPX2, and SPX3.

The partition wall BM may also be referred to as a light-blocking layer in that it includes a light-blocking material to prevent light from the light emitting element LE of a sub-pixel from proceeding to an adjacent sub-pixel.

The partition wall BM may be formed in (e.g., may have) a grid-shaped pattern throughout the display area DA. The partition wall BM may not overlap with the plurality of light emitting elements LE in the third direction DR3. The partition wall BM may serve to provide a space for forming the first light conversion layer QDL1, the second light conversion layer QDL2, and the light transmission layer TPL. The partition wall BM may be formed of an organic insulating material, such as an acrylic resin, epoxy resin, phenolic resin, polyamide resin, polyimide resin, and/or the like.

In one or more embodiments, the partition wall BM is formed as a single layer but is not limited thereto. For example, the partition wall BM may be formed as a double layer. The partition wall BM may be formed as a double layer to sufficiently secure a space for forming the first light conversion layer QDL1, the second light conversion layer QDL2, and the light transmission layer TPL.

The partition wall BM may include a light-blocking material as described above. For example, the partition wall BM may include an inorganic black pigment such as carbon black or an organic black pigment.

A reflective layer RF may be disposed inside a space formed by (e.g., defined by) the partition wall BM. The reflective layer RF may be disposed on a side of the partition wall BM, on the second planarization organic film 180 where the partition wall BM does not overlap with the pixel electrodes PXE1, PXE2, and PXE3, the common electrode CE, and the light emitting element LE. The reflective layer RF may include an opening formed in (e.g., located in) an area that overlaps the pixel electrodes PXE1, PXE2, and PXE3, the common electrode CE, and the light emitting element LE. The reflective layer RF may not be in contact with the pixel electrodes PXE1, PXE2, and PXE3 and the common electrode CE, and may not be electrically connected to them.

On the other hand, the second planarization organic film 180 overlapping the pixel electrode layer (pixel electrodes PXE1, PXE2, and PXE3 and the common electrode CE) may have an undercut shape located inward rather than on the side surface. By adopting such an undercut shape, the reflective layer RF and the pixel electrode layer (pixel electrodes PXE1, PXE2, and PXE3 and the common electrode CE) may be disposed on different layers and may not in contact with each other.

The reflective layer RF serves to reflect light traveling in the side direction from the first light conversion layer QDL1, the second light conversion layer QDL2, and the light transmission layer TPL.

The reflective layer RF may include a metal material having a high light reflectivity. For example, the reflective layer RF may include aluminum and/or silver, and/or an alloy thereof.

In the first sub-pixel SPX1, a first light conversion layer QDL1 may be disposed between two adjacent partition walls BM, in the second sub-pixel SPX2, a second light conversion layer QDL2 may be disposed between two adjacent partition walls BM, and in the third sub-pixel SPX3, a light transmission layer TPL may be disposed between two adjacent partition walls BM.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

A capping layer CAP may be disposed on the partition wall BM, the first light conversion layer QDL1, the second light conversion layer QDL2, and the light transmission layer TPL.

The capping layer CAP may be formed of an inorganic film, such as silicon nitride (SiNₓ), silicon oxide nitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the capping layer CAP.

A fourth organic film 213 may be disposed on the capping layer CAP. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band) and absorb or block the third light (light in the blue wavelength band). Therefore, the first color filter CF1 may transmit the first light (light in the red wavelength band) that has been converted by the first light conversion layer QDL1 from among the third light (light in the blue wavelength band) emitted from the light emitting element LE and absorb or block the third light (light in the blue wavelength band) that has not been converted by the first light conversion layer QDL1. Accordingly, the first sub-pixel SPX1 may emit the first light (light in the red wavelength band).

The second color filter CF2 disposed in the second sub-pixel SPX2 may transmit the second light (light in the green wavelength band) and absorb or block the third light (light in the blue wavelength band). Therefore, the second color filter CF2 may transmit the second light (light in the green wavelength band) that has been converted by the first light conversion layer QDL1 from among the third light (light in the blue wavelength band) emitted from the light emitting element LE and absorb or block the third light (light in the blue wavelength band) that has not been converted by the first light conversion layer QDL1. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the partition wall BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, and/or the like.

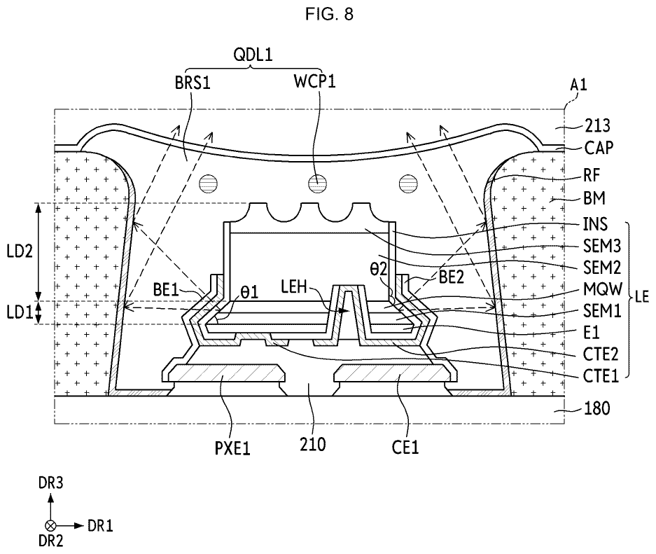

FIG. 8 is a drawing illustrating the direction of travel of light emitted from the light emitting element of FIG. 7.

As shown in FIG. 8, in the case of a light emitting element LE in which a first element rod LD1 including the active layer MQW is in a forward tapered shape, the light emitted to the bottom surface of the light emitting element LE may be reduced and the reflectivity may be increased compared to the light emitting element LE having an inverted taper shape.

Accordingly, the display device according to one or more embodiments may increase the brightness of the display device when the same current is injected as in a conventional display device. Further, the display device according to one or more embodiments may reduce power consumption compared to the same brightness as conventionally.

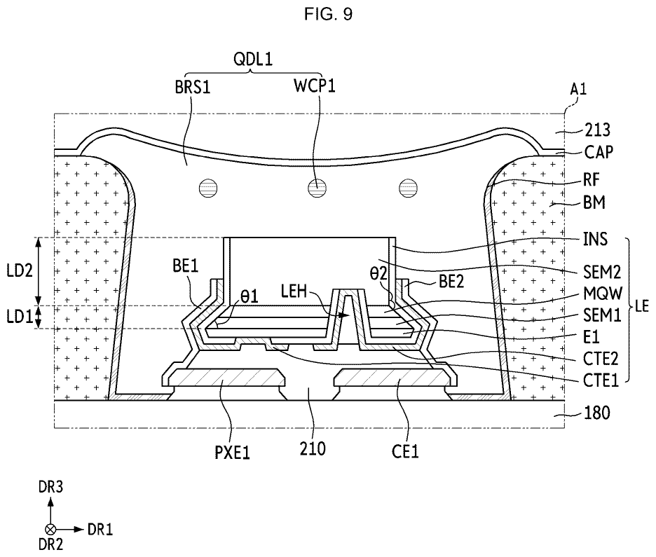

FIG. 9 is a cross-sectional view illustrating another example of the area A1 of FIG. 6 in detail.

The embodiment of FIG. 9 differs from the embodiment of FIG. 7 in that the light emitting element LE does not include a third semiconductor layer SEM3. In FIG. 9, descriptions that overlap with the embodiments described with reference to FIGS. 6 and 7 will not be repeated, and differences from the embodiment of FIG. 7 will be mainly described.

The light emitting element LE may include a conductive layer E1, a first semiconductor layer SEM1, an active layer MQW, a second semiconductor layer SEM2, a first contact electrode CTE1, a second contact electrode CTE2, and a protective film INS.

The first contact electrode CTE1 and the second contact electrode CTE2 are spaced (e.g., spaced apart) from the top surface of the light emitting element LE in the third direction DR3. For example, at least an area adjacent to the top surface of the second semiconductor layer SEM2 may be exposed without being covered by the first contact electrode CTE1 and the second contact electrode CTE2 from among the sides of the plurality of semiconductor layers SEM1, MQW, and SEM2. The first contact electrode CTE1 and the second contact electrode CTE2 may be formed lower (e.g., located below) than at least one end of the passivation film INS.

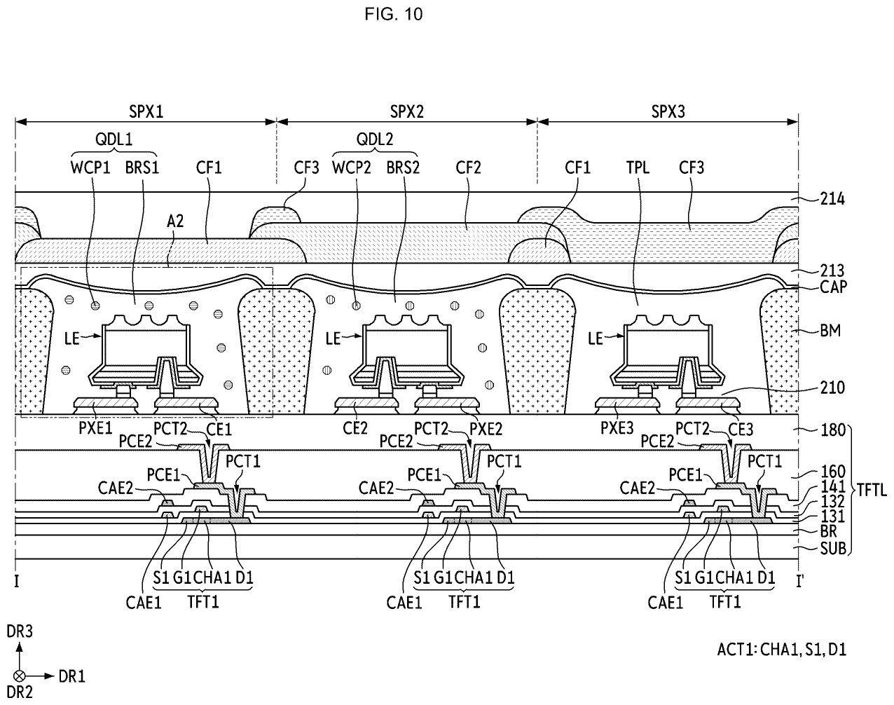

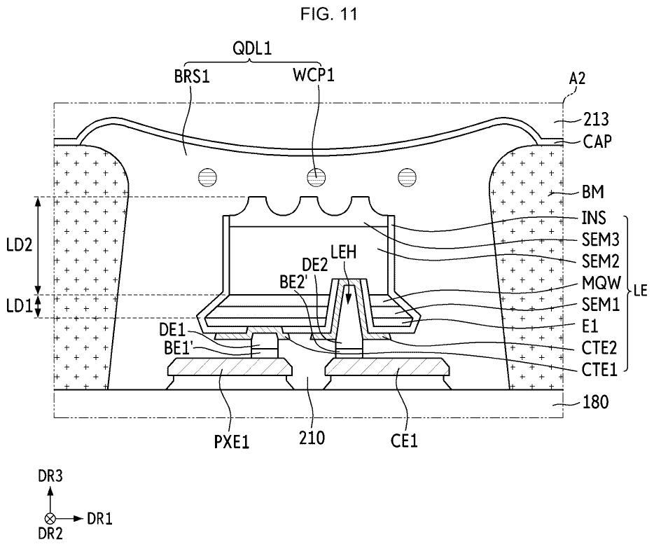

FIG. 10 is a cross-sectional view illustrating an example of a cross-section of a display panel corresponding to the line I-I′ of FIG. 5. FIG. 11 is a cross-sectional view illustrating an example of an area A2 of FIG. 10 in detail.

The embodiments of FIGS. 10 and 11 differ from the embodiment of FIGS. 6 and 7 in that a first electrode DE1 and a second electrode DE2 are disposed between first and second bonding electrodes BE1′, BE2′ and the first and second contact electrodes CTE1, CTE2. In FIGS. 10 and 11, the overlapping descriptions with the embodiments described with reference to FIGS. 6 and 7 will not be repeated, and differences from the embodiments of FIGS. 6 and 7 will be mainly described.

Referring to FIGS. 10 and 11, the light emitting element LE may include a conductive layer E1, a first semiconductor layer SEM1, an active layer MQW, a second semiconductor layer SEM2, a third semiconductor layer SEM3, a first contact electrode CTE1, a second contact electrode CTE2, a first electrode DE1, a second electrode DE2, and a protective film INS.

The first electrode DE1 may be formed to directly contact the first contact electrode CTE1, and the second electrode DE2 may be formed to directly contact (e.g., may directly contact) the second contact electrode CTE2 in the hole LEH. At least one of the first electrode DE1 and the second electrode DE2 protrude above the conductive layer E1.

The first electrode DE1 and the second electrode DE2 may include molybdenum (Mo), aluminum (Al), chromium (Cr), gold (Au), titanium (Ti), nickel (Ni), neodymium (Nd), and/or copper (Cu).

In another embodiment, the first contact electrode CTE1 and the second contact electrode CTE2 may be omitted. In this case, the first electrode DE1 may be formed to directly contact (e.g., may directly contact) the conductive layer E1, and the second electrode DE2 may be formed to directly contact (e.g., may directly contact) the second semiconductor layer SEM2 in the hole LEH.

The first electrode DE1 is disposed on the pixel electrodes PXE1, PXE2, and PXE3, and the second electrode DE2 is disposed on the common electrodes CE1, CE2, and CE3. A first bonding electrode BE1′ may be disposed between the first electrode DE1 and the pixel electrodes PXE1, PXE2, and PXE3. The first bonding electrode BE1′ may serve as a bonding metal for bonding the first electrode DE1 and the pixel electrodes PXE1, PXE2, and PXE3. Similarly, a second bonding electrode BE2′ may be disposed between the second electrode DE2 and the common electrodes CE1, CE2, and CE3, and may serve as a bonding metal for bonding the second electrode DE2 and the common electrodes CE1, CE2, and CE3.

The first bonding electrode BE1′ and the second bonding electrode BE2′ may include gold (Au), copper (Cu), tin (Sn), silver (Ag), aluminum (Al), and/or titanium (Ti). For example, the first bonding electrode BE1′ and the second bonding electrode BE2′ may include a 9:1 alloy of gold and tin, an 8:2 alloy, or a 7:3 alloy.

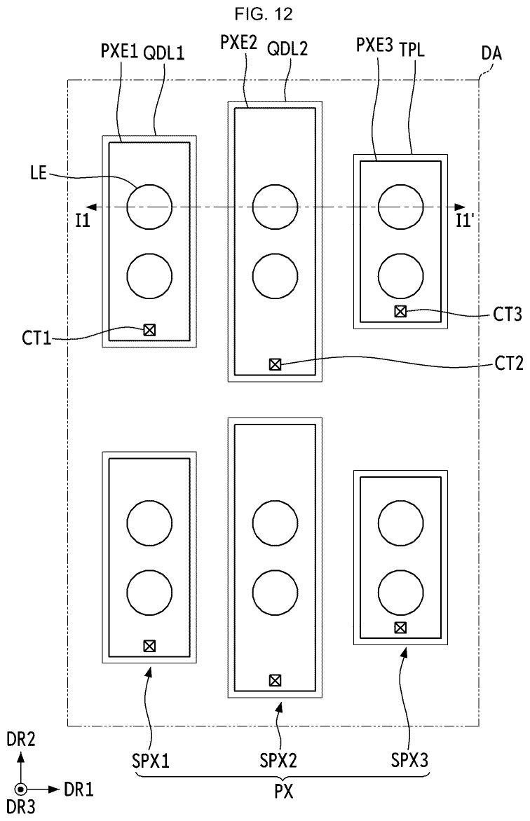

FIG. 12 is a layout drawing illustrating pixels of a display area according to one or more embodiments.

The embodiment of FIG. 12 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 12, the description overlapping with the embodiment of FIG. 5 is omitted.

Referring to FIG. 12, the first sub-pixel SPX1 includes a first pixel electrode PXE1, a plurality of light-emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape having a short side in the first direction DR1 and a long side in the second direction DR2. An area of the first sub-pixel SPX1, an area of the second sub-pixel SPX2, and an area of the third sub-pixel SPX3 may be set depending on the light conversion efficiency of the first light conversion layer QDL1 and the light conversion efficiency of the second light conversion layer QDL2. For example, the area of the sub-pixel may be larger as the light conversion efficiency is lower.

For example, as shown in FIG. 12, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, the area of the first pixel electrode PXE1 may be larger than the area of the third pixel electrode PXE3 because the light transmission layer TPL directly transmits the light of the light emitting element LE, while the first light conversion layer QDL1 need to convert the light,

Each of the pixel electrodes PXE1, PXE2, and PXE3 may be electrically connected to at least one transistor through a pixel connection hole CT1, CT2, and CT3. For example, each of the pixel electrodes PXE1, PXE2, and PXE3 may be electrically connected to the first electrode of the fourth transistor (ST4 of FIG. 4) of the corresponding sub-pixel and the second electrode of the sixth transistor (ST6 of FIG. 4).

The plurality of light emitting elements LE may be arranged on each of the pixel electrodes PXE1, PXE2, and PXE3. The same number of light emitting elements LE may be disposed on each of the pixel electrodes PXE1, PXE2, and PXE3. For example, two light emitting elements LE may be disposed on each of the pixel electrodes PXE1, PXE2, and PXE3.

The first light conversion layer QDL1 may completely overlap the plurality of light emitting elements LE of the first pixel electrode PXE1 and the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the second pixel electrode PXE2 and the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift third light emitted from the plurality of light emitting elements LE of the second sub-pixel SPX2 into second light.

The light transmission layer TPL may completely overlap with the third pixel electrode PXE3 and the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

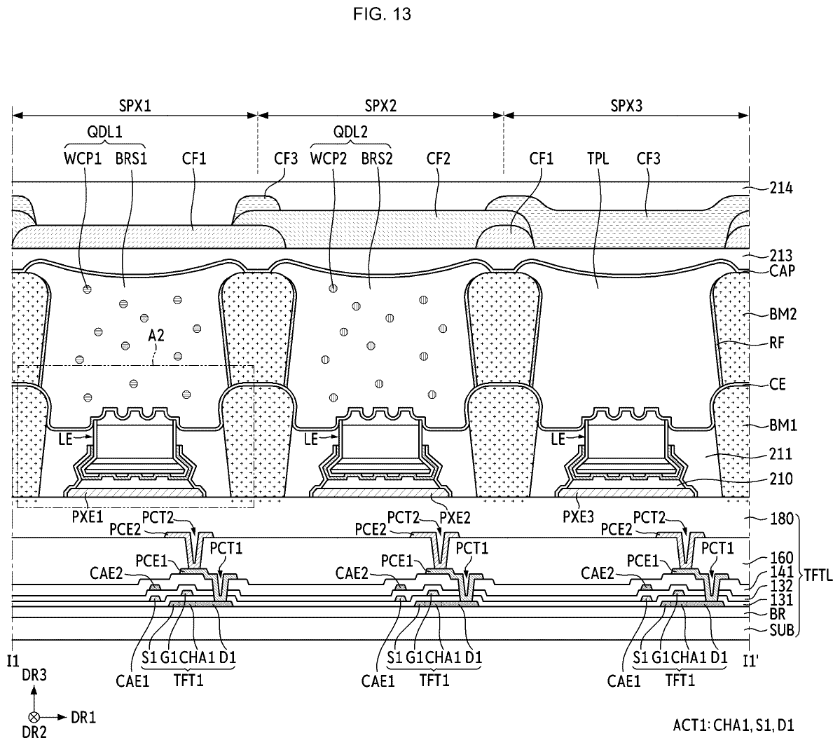

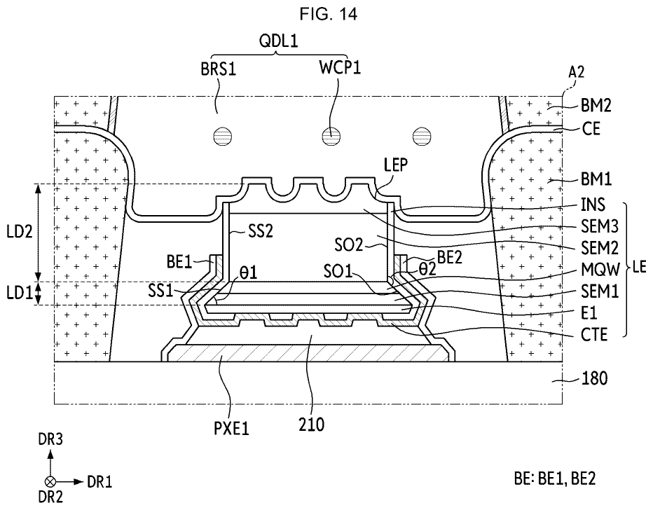

FIG. 13 is a cross-sectional view showing an example of a cross-section of a display panel corresponding to the line I1-I1′ of FIG. 12. FIG. 14 is a cross-sectional view showing an example of an area A2 of FIG. 13 in detail.

The embodiments of FIGS. 13 and 14 differ from the embodiment of FIG. 6 in that the light emitting elements LE are vertical type micro LED in which each of the plurality of light emitting elements LE extends in the third direction DR3. The vertical type micro LED refers to an LED having a structure in which a first semiconductor layer SEM1, an active layer MQW, a second semiconductor layer SEM2, and a third semiconductor layer SEM3 are sequentially disposed along the third direction DR3, which is a vertical direction.

In the embodiments of FIGS. 13 and 14, descriptions that overlap with those of the embodiments of FIGS. 6 and 7 will not be repeated.

Referring to FIGS. 13 and 14, a pixel electrode layer may be disposed on the second planarization organic film 180. The pixel electrode layer may include a first pixel electrode PXE1, a second pixel electrode PXE2, and a third pixel electrode PXE3.

In one or more embodiments, a reflective film may be disposed on the top surface of the first pixel electrode PXE1, the second pixel electrode PXE2, and the third pixel electrode PXE3.

The reflective film may reflect light traveling downward from the light emitting element LE and emit light to the top surface of the light emitting element LE. Therefore, because the loss of light from the light emitting element LE may be reduced, the light efficiency of the light emitting element LE may be increased.

An organic layer 210 is disposed on the first pixel electrode PXE1, the second pixel electrode PXE2, and the third pixel electrode PXE3.

The plurality of light emitting elements LE may be disposed on the organic layer 210. In one or more embodiments, the organic layer 210 may be disposed in an island pattern shape on each sub-pixel SPX1, SPX2, and SPX3. For example, the organic layers 210 disposed in each sub-pixel SPX1, SPX2, and SPX3 may be spaced (e.g., spaced apart) from the organic layers 210 disposed in the adjacent sub-pixels SPX1, SPX2, and SPX3.

Each of the plurality of light emitting elements LE may have a length in the first direction DR1, a length in the second direction DR2, and a length in the third direction DR3 of several to several hundred um, respectively. For example, each of the plurality of light emitting elements LE may have a length in the first direction DR1 a length in the second direction DR2, and a length in the third direction DR3 of approximately 100 μm or less, respectively.

The light emitting element LE may include a conductive layer E1, a first semiconductor layer SEM1, an active layer MQW, a second semiconductor layer SEM2, a third semiconductor layer SEM3, a contact electrode CTE, and a protective film INS.

The light emitting element LE may be divided into a conductive layer E1, a first element rod LD1, a second element rod LD2, and a contact electrode CTE.

The first element rod LD1 may be disposed closer to the second planarization organic film 180 than the second element rod LD2. The first element rod LD1 has a tapered shape with a width that decreases toward the top. The first element rod LD1 may include a first semiconductor layer SEM1 and an active layer MQW. Therefore, the width of the first semiconductor layer SEM1 in the first element rod LD1 is wider than the width of the active layer MQW.

When the first element rod LD1 has a tapered shape, the light extraction effect may be improved compared to the reverse tapered shape.

For example, for convenience of explanation, the inner side of the first element rod LD1 is referred to as the first inner side SS1 and the inner side of the second element rod LD2 is referred to as the second inner side SS2. The outer side of the first element rod LD1 is referred to as the first outer side SO1 and the outer side of the second element rod LD2 is referred to as the second outer side SO2.

The first element rod LD1 may have a first inclination angle θ1 formed between the first inner side SS1 and one surface of the first semiconductor layer SEM1 of the first element rod LD1 may be about 20° to 65°.

The second inclination angle θ2 formed between the second outer side SO2 of the second element rod LD2 and the first outer side SO1 of the first element rod LD1 may be about 110° to 155°.

The second element rod LD2 is disposed on the first element rod LD1 and may include a side surface that is relatively vertical compared to the first element rod LD1. The second element rod LD2 may have a width of a top surface and a width of a bottom surface that are substantially the same. For example, the second semiconductor layer SEM2 may have a cross-sectional shape that is substantially the same as a rectangle or square. The width of the third semiconductor layer SEM3 of the second element rod LD2 is narrower than the width of the active layer MQW.

The second element rod LD2 may secure the volume of the second semiconductor layer SEM2 by forming a side surface that is vertical compared to the tapered shape and may reduce or maximize the injection of electron carriers into the active layer MQW. For example, when the second element rod LD2 is formed in (e.g., may have) the same tapered shape as the first element rod LD1, the width of the top surface of the second semiconductor layer SEM2 becomes narrower than the width of the bottom surface, so that the volume of the second semiconductor layer SEM2 decreases.

The protective film INS may be disposed on the side of the first semiconductor layer SEM1, the side of the active layer MQW, the side of the second semiconductor layer SEM2, the side of the third semiconductor layer SEM3, and the side and bottom surface of the conductive layer E1. The protective film INS may be a film for protecting the side of the light emitting element LE. The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

In each light emitting element LE, a contact electrode CTE may be disposed on the protective film INS. The contact electrode CTE may be disposed between the organic layer 210 and the protective layer INS.

The protective layer INS has one or more openings exposing the conductive layer E1. In one or more embodiments, the protective layer INS includes two openings.

The contact electrode CTE may be connected to the conductive layer E1 that is exposed and not covered by the protective layer INS.

The contact electrode CTE may be disposed on at least a portion of a side surface of the light emitting element LE. At least an area of the side surface of the light emitting element LE adjacent to the top surface of the light emitting element LE may be exposed and not covered by the contact electrode CTE. For example, the contact electrode CTE is spaced (e.g., spaced apart) from the top surface of the light emitting element LE in the third direction DR3.

When the contact electrode CTE is formed of a metal with high reflectivity, light that propagates in the lateral direction of the light emitting element LE may be reflected by the contact electrode CTE and emitted to the top surface of the light emitting element LE from among the light emitted from the active layer MQW of the light emitting element LE. Therefore, because the loss of light from the light emitting element LE may be reduced, the light efficiency of the light emitting element LE may be increased. Therefore, it is preferable that the contact electrode CTE is disposed to cover most of the lateral surface of the light emitting element LE to increase the light efficiency of the light emitting element LE.

The contact electrode CTE may include molybdenum (Mo), aluminum (AI), chromium (Cr), gold (Au), titanium (Ti), nickel (Ni), neodymium (Nd), and/or copper (Cu). Specifically, the contact electrode CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The connection electrode BE (BE1, BE2) connects the contact electrode CTE of the light emitting element LE and the pixel electrode PXE1, PXE2, and PXE3.

In one or more embodiments, the connection electrode BE is disposed on the contact electrode CTE disposed on the side of the plurality of semiconductor layers SEM1, MQW, SEM2, and SEM3, extends along the organic layer 210, and may contact the pixel electrode PXE1, PXE2, and PXE3. Accordingly, the connection electrode BE may connect the conductive layer E1 of the light emitting element LE and the pixel electrode PXE1, PXE2, and PXE3.

The connection electrode BE may expose an area adjacent to the top surface of the third semiconductor layer SEM3 from among the side surfaces of the plurality of semiconductor layers SEM1, MQW, SEM2, and SEM3 without being covered by the connection electrode BE.

A first partition wall BM1 and a second organic film 211 that divide each light emitting area EA1, EA2, and EA3 may be further disposed on the second planarization organic film 180.

The first partition wall BM1 may not overlap the plurality of light emitting elements LE in the third direction DR3.

The first partition wall BM1 may be formed by a negative photoresist and may have a reverse taper shape but is not limited thereto.

The light emitting element LE and the second organic film 211 may be placed within a space formed by (or defined by) two adjacent first partition walls BM1. The second organic film 211 may be disposed to cover a portion of a side surface of a plurality of light emitting elements LE. Further, the second organic film 211 may be disposed on the connection electrode BE and the protective film INS.

The top surface of each of the plurality of light emitting elements LE may be exposed without being covered by the second organic film 211. The second organic film 211 is a layer for flattening a step caused by the plurality of light emitting elements LE.

The second organic film 211 may be formed from an organic film such as an acrylic resin, an epoxy resin, a phenolic resin, a polyamide resin, a polyimide resin, and/or the like.

The common electrode CE may be arranged on the upper surface of each of the plurality of light emitting elements LE and the top surface of the second organic film 211. The common electrode CE may be a common layer formed commonly on the first sub-pixel SPX1, the second sub-pixel SPX2, and the third sub-pixel SPX3. The common electrode CE may be made of a transparent conductive material (TCO) such as indium tin oxide (ITO) and indium zinc oxide (IZO) that may transmit light.

A second partition wall BM2 may be further disposed on the first partition wall BM1.

The second partition wall BM2 may serve to provide a space for forming the first light conversion layer QDL1, the second light conversion layer QDL2, and the light transmission layer TPL.

A reflective layer RF may be disposed inside the space formed by (or defined by) the second partition wall BM2. The reflective layer RF may be disposed on the side of the second partition wall BM2.

A capping layer CAP may be disposed on the second partition wall BM2, the first light conversion layer QDL1, the second light conversion layer QDL2, and the light transmission layer TPL.

A fourth organic film 213 may be disposed on the capping layer CAP. A plurality of color filters CF1, CF2, and CF3 may be disposed on the fourth organic film 213. The plurality of color filters CF1, CF2, and CF3 may include first color filters CF1, second color filters CF2, and third color filters CF3.

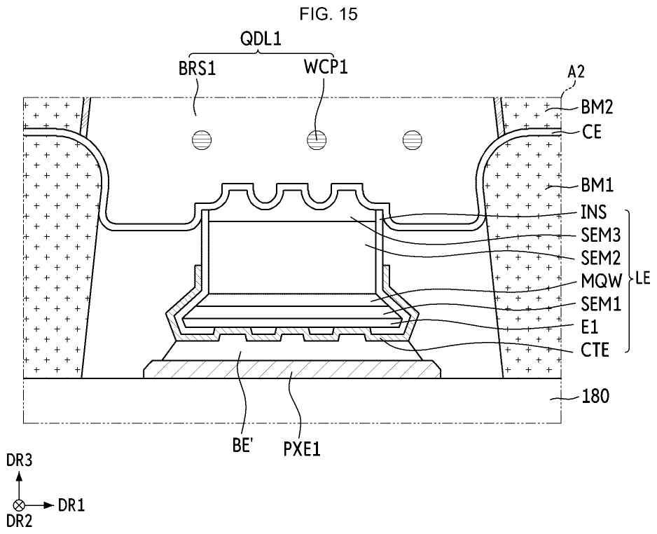

FIG. 15 is a cross-sectional drawing illustrating another example of the area A2 of FIG. 13 in detail.

The embodiment of FIG. 15 is different from the embodiment of FIG. 14 in that an organic layer (210 of FIG. 14) is not disposed between the light emitting element LE and the pixel electrodes PXE1, PXE2, and PXE3. In FIG. 15, descriptions that are overlapping with the embodiment described with reference to FIGS. 13 and 14 will not be repeated, and differences from the embodiment of FIGS. 13 and 14 will be mainly described.

Referring to FIG. 15, a bonding electrode BE′ may be disposed between the light emitting element LE and the pixel electrodes PXE1, PXE2, and PXE3. The bonding electrode BE′ may serve as a bonding metal for bonding the contact electrode CTE and the pixel electrodes PXE1, PXE2, and PXE3. The bonding electrode BE′ may include gold (Au), copper (Cu), tin (Sn), silver (Ag), aluminum (Al), and/or titanium (Ti). For example, the bonding electrode BE1′ may include a 9:1 alloy of gold and tin, an 8:2 alloy, and/or a 7:3 alloy.

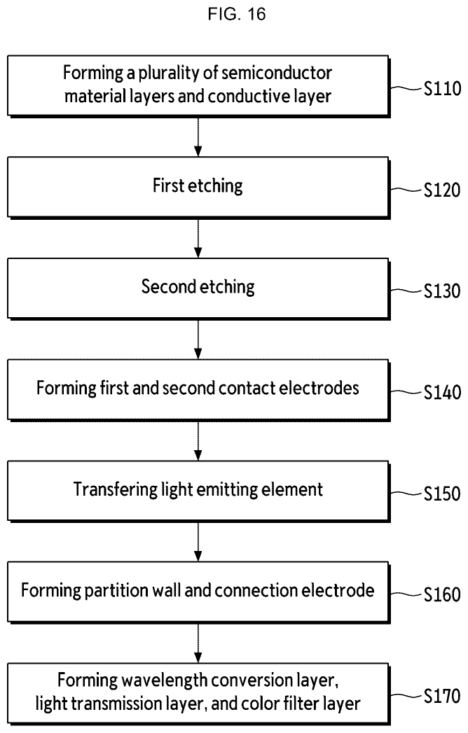

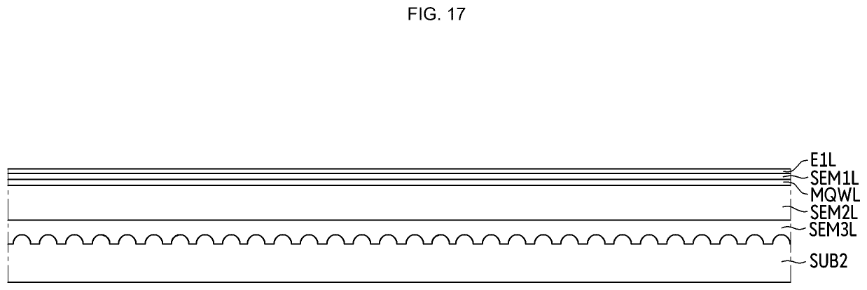

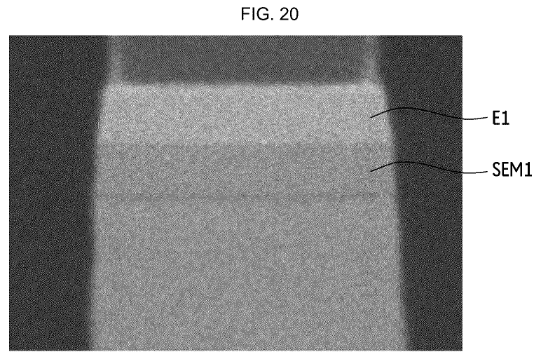

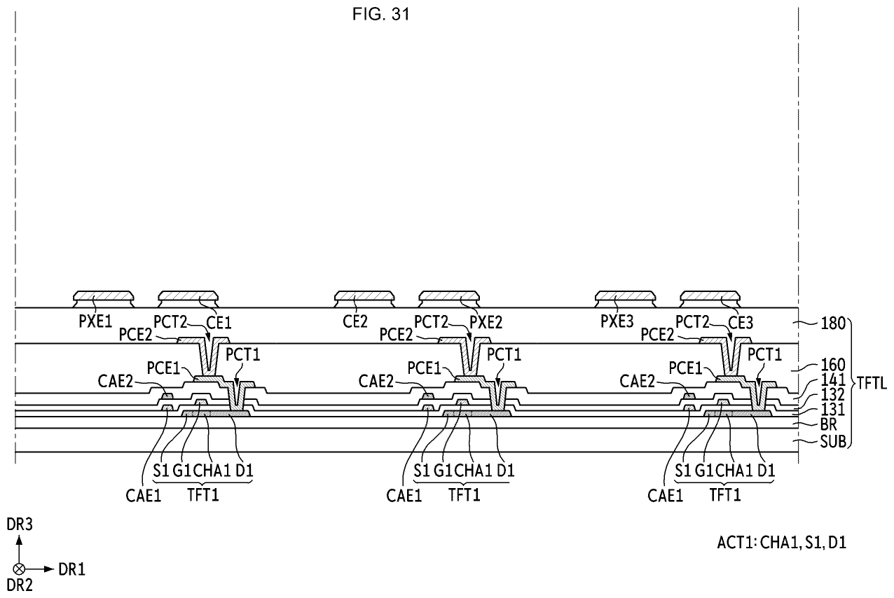

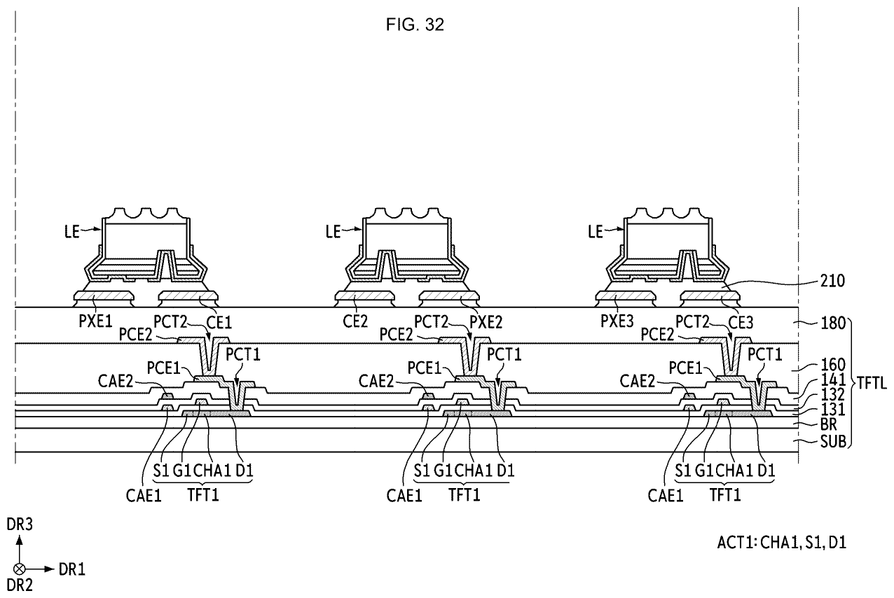

FIG. 16 is a flowchart illustrating a method of manufacturing a display device according to one or more embodiments. FIGS. 17-35 are exemplary drawings to illustrate a method of manufacturing a display device according to one or more embodiments. FIGS. 20, 22, 24, and 26 are microscopic photographs of a conductive layer and a plurality of semiconductor layers according to a manufacturing method of one embodiment.

Hereinafter, a manufacturing method of a display device according to one or more embodiments will be described in detail by connecting FIG. 16 with FIGS. 17-35. The manufacturing method of the display device described with reference to FIGS. 16-35 may be a display device including a light emitting element and a display panel described with reference to FIGS. 5-7.

First, a plurality of semiconductor material layers SEM3L, SEM2L, MQWL, and SEM1L, and a conductive layer E1L are formed on a second substrate SUB2. (S110 of FIG. 16)

First, a second substrate SUB2 is prepared. The second substrate SUB2 may be a sapphire substrate Al₂O₃ and/or a transparent silicon wafer including silicon. However, it is not limited thereto, and in one or more embodiments, a case in which the second substrate SUB2 is a sapphire substrate is described as an example.

A plurality of semiconductor material layers SEM3L, SEM2L, MQWL, SEM1L are formed on a second substrate SUB2. The plurality of semiconductor material layers grown by the epitaxial method may be formed by growing a seed crystal. Methods for forming semiconductor material layers include electron beam deposition, physical vapor deposition (PVD), chemical vapor deposition (CVD), and/or plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

Specifically, a third semiconductor material layer SEM3L is formed on the second substrate SUB2. In the drawing, the third semiconductor layer SEM3 is illustrated as being laminated in one layer but is not limited thereto, and a plurality of layers may be formed. The third semiconductor material layer SEM3L may be disposed to reduce the lattice constant difference between the second semiconductor material layer SEM2L and the second substrate SUB2. In one example, the third semiconductor material layer SEM3L may include an undoped semiconductor and may be a material that is not doped as n-type or p-type. In one or more embodiments, the third semiconductor material layer SEM3L may be at least one of undoped InAIGaN, GaN, AlGaN, InGaN, AlN, and/or InN but is not limited thereto.

The second semiconductor material layer SEM2L, the active material layer MQWL, and the first semiconductor material layer SEM1L are sequentially formed on the third semiconductor material layer SEM3L using the above-described method.

Next, a conductive layer E1L is deposited on the semiconductor material layer SEM3L, SEM2L, MQWL, and SEM1L. The conductive layer E1L may include, but not limited to, molybdenum (Mo), aluminum (Al), chromium (Cr), gold (Au), titanium (Ti), nickel (Ni), neodymium (Nd), and/or copper (Cu).

Second, a first etching is performed by forming a double mask on the conductive layer E1L (S120 of FIG. 160). The first etching may be performed by dry etching. When using the dry etching method, the etching gas may be chlorine (Cl₂) or oxygen (O₂) gas but is not limited thereto.

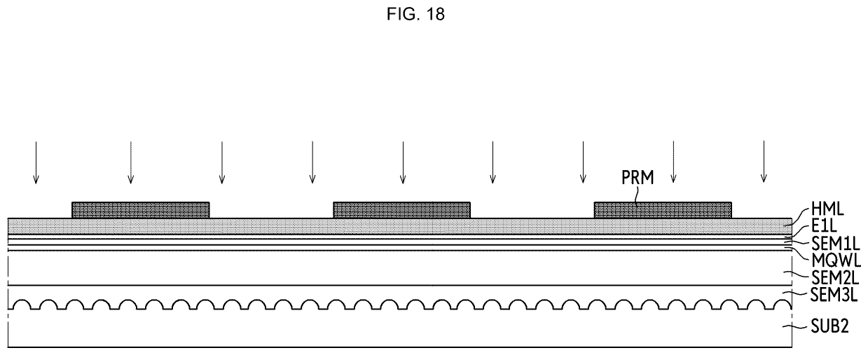

Referring to FIG. 18, a hard mask material layer HML is formed on the conductive layer E1L. The hard mask material layer HML may be formed of silicon oxide (SiOx). A patterned photoresist mask PRM is formed on the hard mask material layer HML. The photoresist is a photosensitive material and is an organic solution of resin and a photosensitive agent. Therefore, the photoresist mask PRM is also formed of a photosensitive material.

Then, the hard mask material layer HML is patterned through a dry etching process using the patterned photoresist mask PRM as a mask. The upper portion of the conductive layer E1L in an area that does not overlap with the patterned photoresist mask PRM may be exposed by the dry etching process. Then, the photoresist mask PRM pattern is removed by ashing. Afterwards, the conductive layer E1L, the first semiconductor material layer SEM1L, the active material layer MQWL, and the second semiconductor material layer SEM2L are etched using the patterned hard mask material layer HML as a mask.

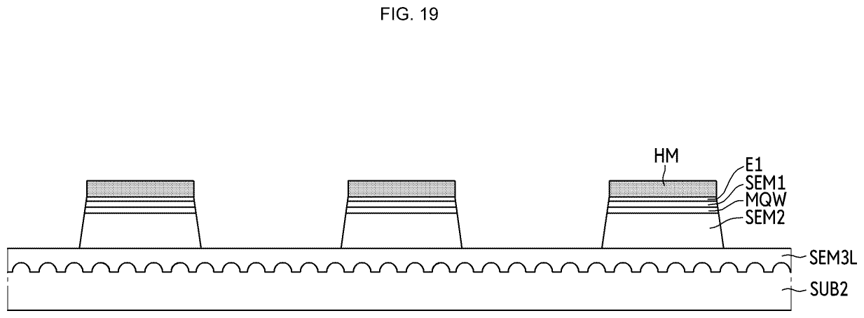

Referring to FIGS. 19 and 20, the width of the plurality of semiconductor material layers may become wider towards the bottom by dry etching. For example, the width of the first semiconductor layer SEM1 may be narrower than the width of the active layer MQW, and the width of the active layer MQW may be narrower than the width of the second semiconductor layer SEM2. The third semiconductor layer SEM3 may not be etched.

Dry etching is a method that uses a highly chemically reactive gas instead of a liquid chemical solution. As the etching depth increases during dry etching, the process time increases, and because the plasma exposure time of the semiconductor material layer increases, the damage to the active layer may increase.

Third, the secondary etching is performed using a hard mask (S130 of FIG. 160). The secondary etching may be performed by wet etching.

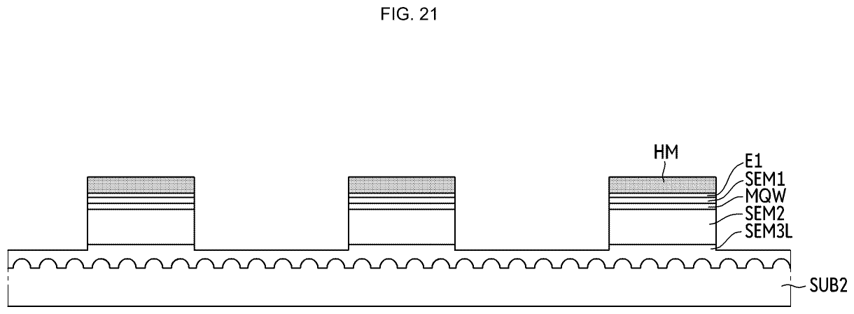

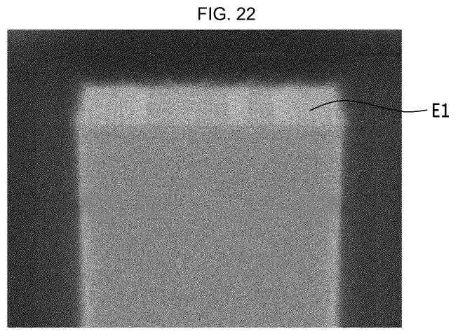

Referring to FIGS. 21 and 22, when wet etching is performed using a hard mask, plurality of semiconductor layers protruding outside the hard mask may be etched to form a plurality of semiconductor layers that are nearly vertical.

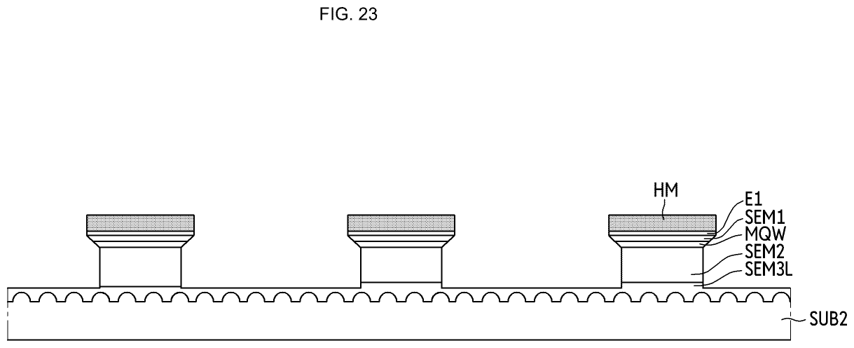

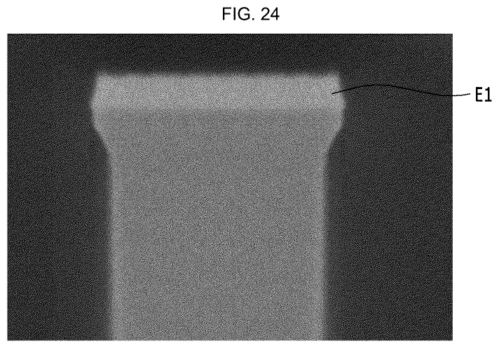

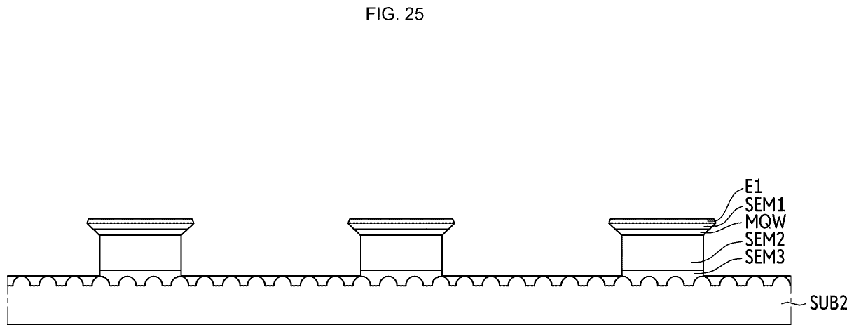

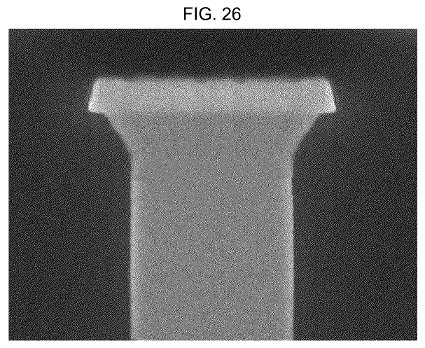

Wet etching is a method of etching by causing a chemical reaction with a thin film material to be removed using a chemical solution. Because the chemical reaction occurs at the contacted area to remove the thin film material, a new chemical solution must be continuously brought into contact with the thin film surface in order for the chemical reaction on the surface to proceed smoothly. Wet etching has the advantage of being highly selective because it does not react with materials that are not chemically reactive. For example, the etching rate of the first semiconductor layer SEM1 is lower than the etching rate of the active layer MQW, and the etching rate of the second semiconductor layer SEM2 is lower than the etching rate of the active layer MQW. Accordingly, because the etching rate of the second semiconductor layer SEM2 is higher than that of the first semiconductor layer SEM1, the etching amount of the second semiconductor layer SEM2 will be greater than that of the first semiconductor layer SEM1 as time passes. For example, after a first hour (e.g., 15 minutes) has passed since the start of wet etching, the side surfaces of the plurality of semiconductor layers may be formed almost vertically, as shown in FIGS. 21 and 22. Then, as a second hour has passed since the start of wet etching, the etching amount of the second semiconductor layer SEM2 will be greater than that of the first semiconductor layer SEM1. For example, FIGS. 23 and 24 are shapes of the plurality of semiconductor layers SEM1, MQW, and SEM2 after a third time (e.g., 30 minutes) has passed since the start of wet etching, and FIGS. 25 and 26 are shapes of the plurality of semiconductor layers SEM1, MQW, SEM2, and SEM3 after a fourth time (e.g., 150 minutes) has passed since the start of wet etching.

In this way, each semiconductor layer may be formed at a desired inclination angle by adjusting the wet etching time, etc.

Fourth, the first contact electrode CTE1 and the second contact electrode CTE2 are formed. (S140 of FIG. 160)

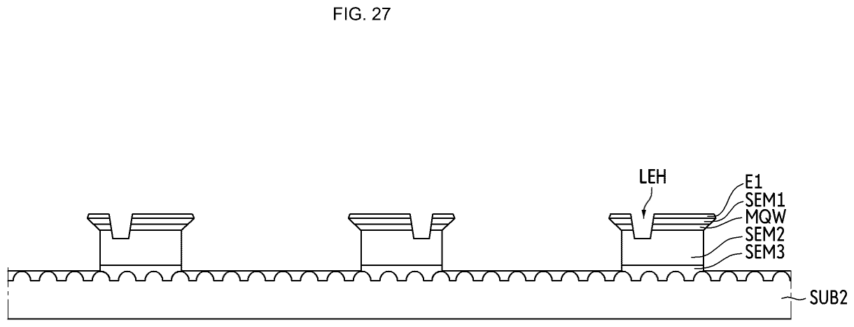

For example, referring to FIG. 27, in one or more embodiments, a portion of the upper portion of the conductive layer E1 is covered using a mask, and a hole LEH is formed that penetrates the conductive layer E1, the first semiconductor layer SEM1, and the active layer MQW in each of the light emitting elements LE where the mask is not placed to expose the second semiconductor layer SEM2.

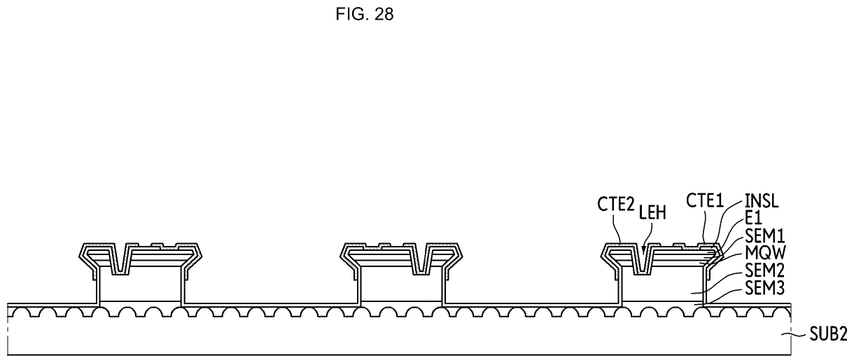

Next, referring to FIG. 28, the protective material layer INSL may be entirely deposited on one surface of the second substrate SUB2. The protective material layer INSL may be formed to cover one surface and side surfaces of the light emitting elements LE. The protective material layer INSL may be formed on one surface of the second substrate SUB2 exposed between the light emitting elements LE.

Then, the first mask may be used to form a portion of the hole LEH of each of the light emitting elements LE. For example, the first mask may be used to form a portion of the protective material layer INSL disposed on the bottom surface of the hole LEH of each of the light emitting elements LE.

In addition, in dry etching, when a large up-down voltage difference is formed and the protective material layer INSL is etched, the etching gas proceeds in the third direction DR3 and etches the protective material layer INSL. As a result, the protective material layer INSL disposed on the sidewall of the hole LEH of each of the light emitting elements LE may remain without being etched even if it is not protected by the first mask pattern. Accordingly, the protective material layer INSL disposed on the bottom surface of the hole LEH of each of the light emitting elements LE is etched, and the second semiconductor layer SEM2 in the hole LEH of each of the light emitting elements LE may be exposed without being covered by the protective material layer INSL.

Then, the first mask may be removed by an ashing process.

Thereafter, etching is performed to expose a portion of the upper surface of the conductive layer E1 and the bottom surface inside the hole LEH. Next, an electrode material layer is formed on the entire surface of the second substrate SUB2 to cover all of the plurality of semiconductor layers SEM1, MQW, and SEM2 on the protective material layer INSL. Then, a portion of the electrode material layer is etched using a photoresist to form a first contact electrode CTE1 and a second contact electrode CTE2. The first contact electrode CTE1 may contact the first conductive layer E1, and the second contact electrode CTE2 may contact the second semiconductor layer SEM2.

Fifth, the light emitting element LE is transferred to the substrate SUB. (S150 of FIG. 160)

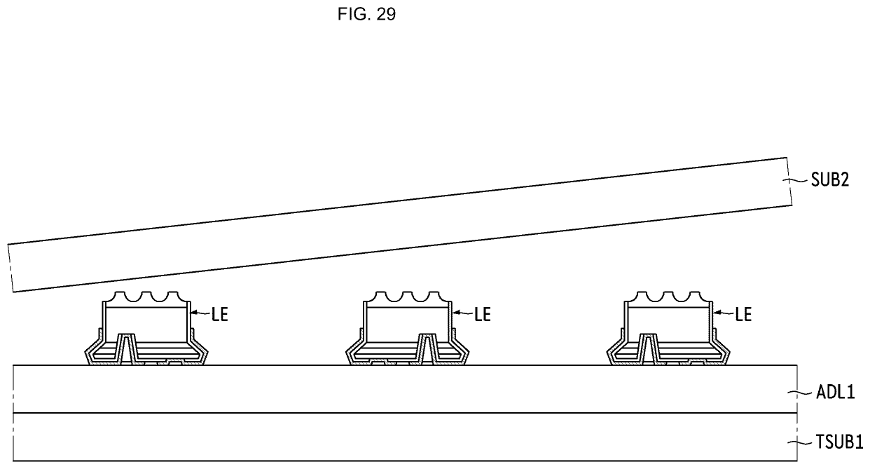

Referring to FIG. 29, a plurality of light emitting elements LE of the second substrate SUB2 are moved to the first adhesive layer ADL1 disposed on the first transfer substrate TSUB1.

The first transfer substrate TSUB1 may be made of a transparent material that allows light to pass through. For example, the first transfer substrate TSUB1 may include a transparent polymer such as polyimide, polyester, polyacrylic, polyepoxy, polyethylene, polystyrene, polyethylene terephthalate, and/or the like. The first adhesive layer ADL1 disposed on one side of the first transfer substrate TSUB1 may include an adhesive material for bonding the plurality of light emitting elements LE. For example, the adhesive material may include urethane acrylate, epoxy acrylate, polyester acrylate, and/or the like.

The first contact electrode CTE1 and the second contact electrode CTE2 of each of the plurality of light emitting elements LE may be bonded to the first adhesive layer ADL1 disposed on the first transfer substrate TSUB1. Then, the plurality of light emitting elements LE may be separated from the semiconductor substrate SSUB by a laser lift off (LLO) process of irradiating the semiconductor substrate SSUB with a laser. The laser may be a KrF excimer laser having a wavelength of approximately 248 nm, but the present disclosure is not limited thereto.

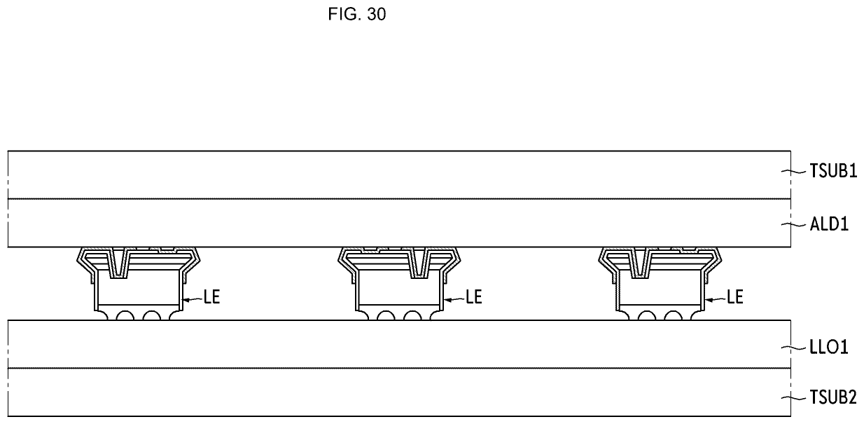

Referring to FIG. 30, a plurality of light emitting elements LE of a first transfer substrate TSUB1 are moved to a first laser separation layer LLO1 disposed on a second transfer substrate TSUB2.

The second transfer substrate TSUB2 may be made of a transparent material that allows light to pass through. For example, the second transfer substrate TSUB2 may include a transparent polymer such as polyimide, polyester, polyacrylic, polyepoxy, polyethylene, polystyrene, polyethylene terephthalate, and/or the like. The first laser separation layer LLO1 disposed on the second transfer substrate TSBU2 is a layer that may be separated by laser irradiation, and may include a transparent polymer, such as polyimide, for example.

When heat is applied while one surface of each of the plurality of light emitting elements LE is in contact with the first laser separation layer LLO1, each of the plurality of light emitting elements LE may be adhered or fixed to the first laser separation layer LLO1, and each of the plurality of light emitting elements LE may be separated from the first adhesive layer ADL1 as the adhesive strength of the first adhesive layer ADL1 is weakened. One surface of each of the plurality of light emitting elements LE may be the opposite surface of the other surface on which the first adhesive electrode CTE1 and the second adhesive electrode CTE2 are disposed in each of the plurality of light emitting elements LE.

Next, an organic layer 210 is formed on a second planarizing organic film 180 on which pixel electrodes PXE1, PXE2, and PXE3 and common electrodes CE1, CE2, and CE3) are disposed, and then a second transfer substrate TSUB2 is bonded so that the light emitting elements LE are disposed on the organic layer 210.

If the organic layer 210 is a photosensitive organic film such as a photoresist, the organic layer 210 may be hardened (soft baked) at a first temperature when forming the organic layer 210. Then, after the light emitting element LE is disposed on the organic layer 210, the organic layer 210 may be completely hardened at a second temperature higher than the first temperature. The first temperature may be approximately 100 degrees, and the second temperature may be approximately 230 degrees, but the present disclosure is not limited thereto. Also, the process of completely hardening the organic layer 210 at the second temperature may be performed for approximately 30 minutes.

Therefore, the bonding process using the organic layer 210 may bond the light emitting element LE to the substrate SUB at a relatively lower temperature and pressure compared to the eutectic bonding process.

Then, the second transfer substrate TSUB2 is separated from the plurality of light emitting elements LE.

Sixth, the partition wall BM and the connection electrode BE1 and BE2 are formed. (S160 of FIG. 160)

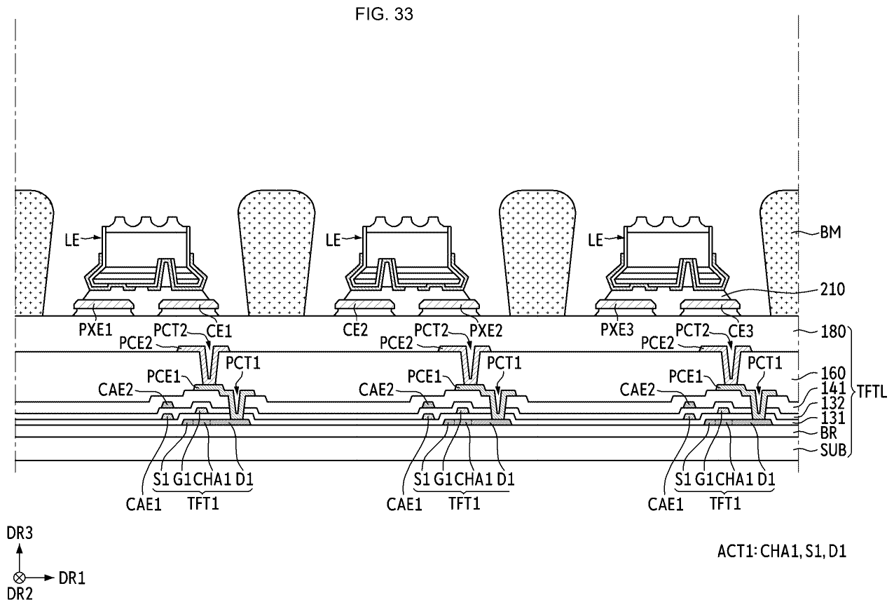

First, referring to FIG. 33, the partition wall BM is formed on the second planarization organic film 180. For example, the partition wall BM is formed on the second planarization organic film 180 using a negative photoresist. Since the negative photoresist dissolves in the portion that is not exposed to light, the partition wall BM may be formed in a reverse taper shape whose width becomes narrower towards the bottom.

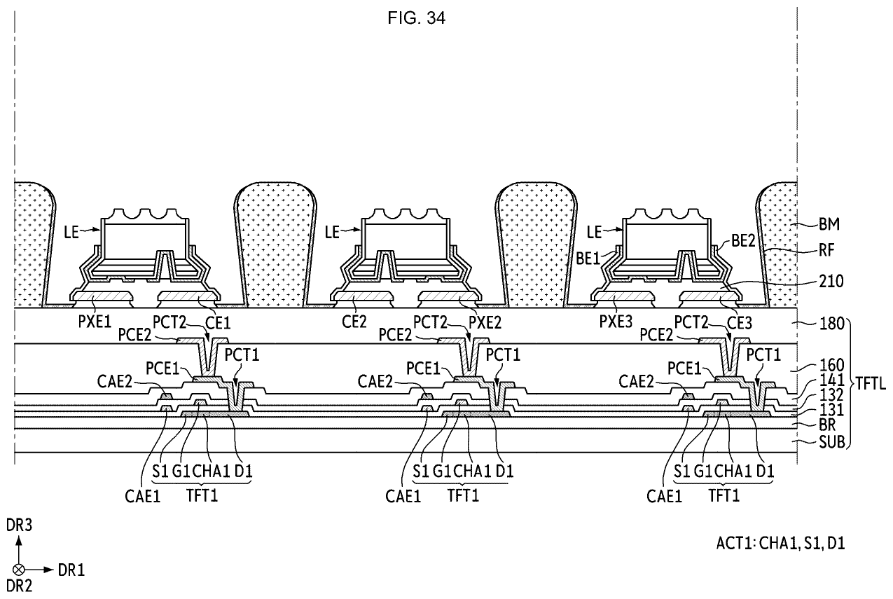

Next, referring to FIG. 34, a reflective material layer is deposited on the entire surface of the substrate SUB on which the partition wall BM is formed. The reflective material layer may be formed to cover both the partition wall BM and the light-emitting element LE. The reflective material layer is formed on the top surface side surface of the partition wall BM, the top surface and side surface of the light emitting element LE, as well as on the bottom between the light emitting element LE and the partition wall BM.

The reflective material layer is formed on the top surface and side surface of the partition wall BM, the top surface and side surface of the light emitting element LE, as well as on the bottom between the light emitting element LE and the partition wall BM (the top surface of the second planarization organic film 180). The reflective material layer is disposed along the side surface of the light emitting element LE, the side surface of the organic layer 210, the side surface of the first pixel electrode PXE1, and the side surface of the first common electrode CE1 but is disconnected by the undercut-shaped structure of the second planarization organic film 180. Specifically, the reflective material layer disposed along the side of the light emitting element LE, the side of the organic layer 210, the side of the first pixel electrode PXE1, and the side of the first common electrode CE1, and the reflective material layer disposed along the partition wall BM are disposed discontinuously.

A portion of the reflective material layer, such as the upper surface of the partition wall BM, may be removed to form the reflective layer RF, the first connection electrode BE1, and the second connection electrode BE2.

Seventh, a wavelength conversion layer, a light transmission layer, and a color filter layer are sequentially formed. (S170 of FIG. 16)

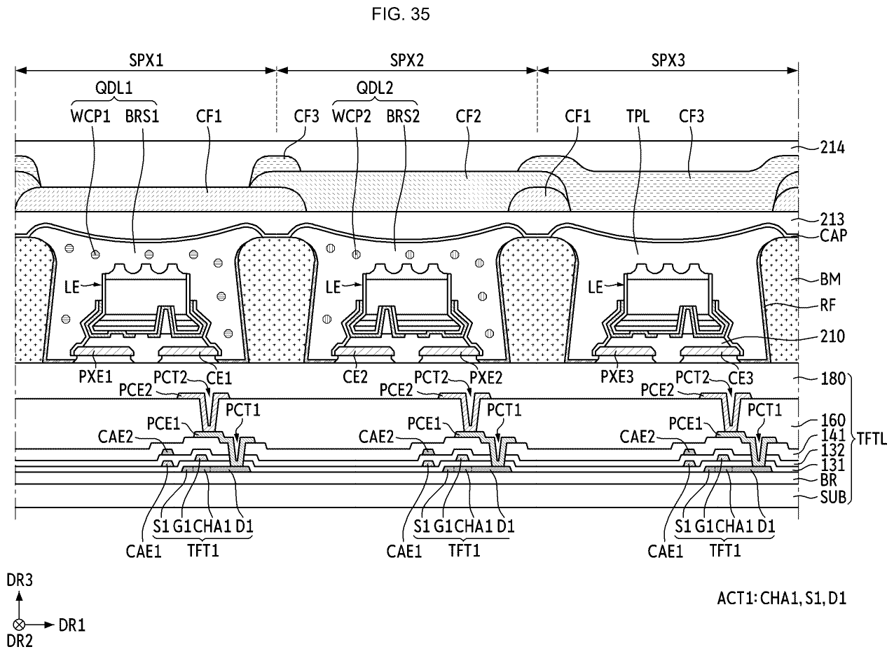

Referring to FIG. 35, a first light conversion layer QDL1 is formed in each of the first sub-pixels SPX1, the second light conversion layer QDL2 is formed in each of the second sub-pixels SPX2, and the light transmission layer TPL is formed in each of the third sub-pixels SPX3. Then, a capping layer CAP covering the first light conversion layers QDL1, the second light conversion layers QDL2, and the light transmission layers TPL is formed. Then, a second organic film 213 is formed on the capping layer CAP.

Then, a first color filter CF1 overlapping the first light conversion layers QDL1 in the third direction DR3 is formed on the second organic film 213, a second color filter CF2 overlapping the second light conversion layers QDL2 in the third direction DR3 is formed, and a third color filter CF3 overlapping the light transmission layers TPL in the third direction DR3 is formed. In the third direction DR3, the first color filter CF1, the second color filter CF2, and the third color filter CF3 may all be formed in an area overlapping the partition wall BM.

Then, a fifth organic film 214 is formed on the first color filter CF1, the second color filter CF2, and the third color filter CF3.

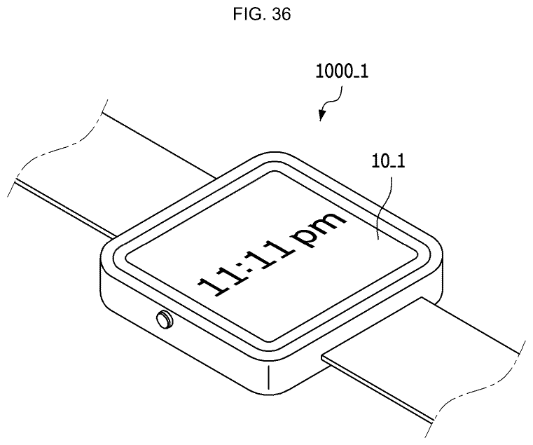

FIG. 36 is an example view of a smart watch including a display device according to one or more embodiments.

Referring to FIG. 36, a display device 10_1 according to one or more embodiments may be applied to a smart watch 1000_1 which is one of smart devices.

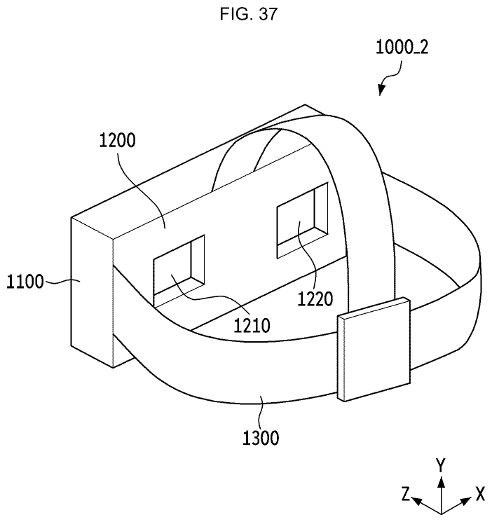

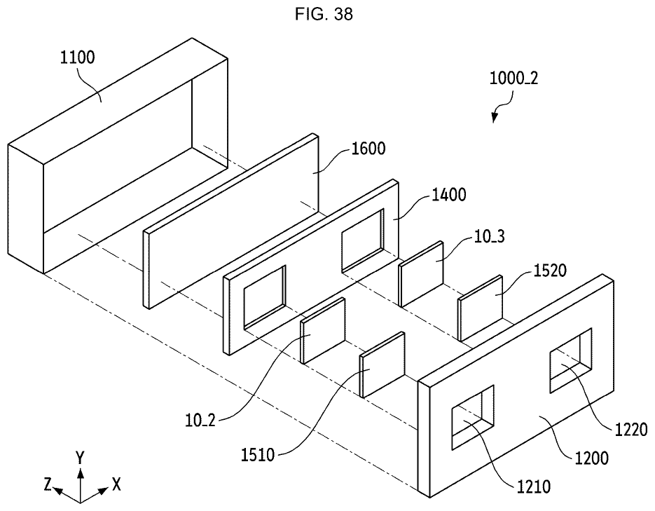

FIGS. 37 and 38 are example views of a virtual reality (VR) device including a display device according to one or more embodiments.

Referring to FIGS. 37 and 38, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 33 and 34, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

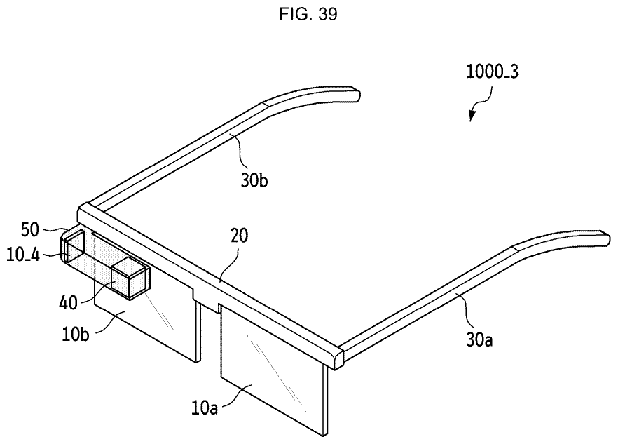

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 39 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 39 is an example view of a VR device including a display device according to one or more embodiments. FIG. 39 illustrates a VR device 1000_3 to which a display device 10_4 according to one or more embodiments has been applied.

Referring to FIG. 39, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 39, a case where the VR device 1000_3 is a glasses-type display device including the eyeglass frame legs 30a and 30b is illustrated as an example. That is, the VR device 1000_3 according to the embodiment is not limited to the one illustrated in FIG. 39 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 39, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

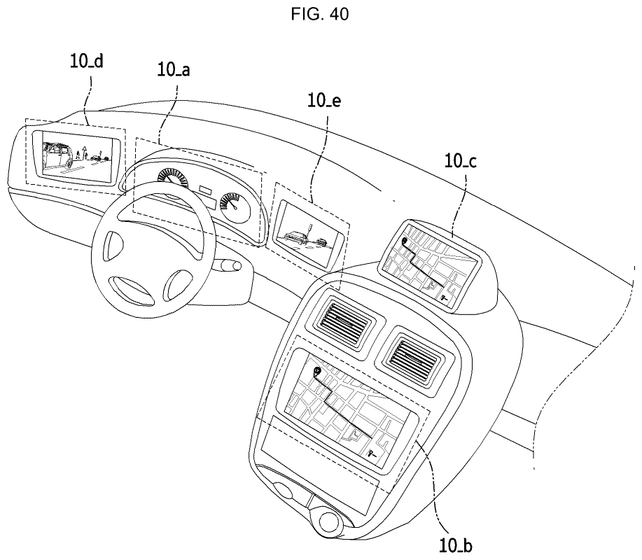

FIG. 40 is an example view illustrating a vehicle instrument cluster and center fascia including display devices according to one or more embodiments. FIG. 40 illustrates a vehicle to which display devices 10_a through 10_e according to one or more embodiments have been applied.

Referring to FIG. 40, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

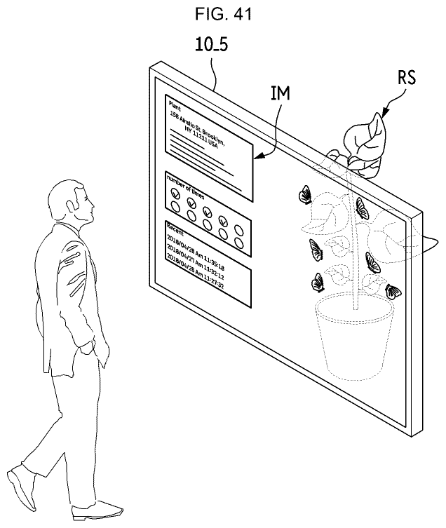

FIG. 41 is an example view of a transparent display device including a display device according to one or more embodiments.

Referring to FIG. 41, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

1 what is claimed is:

1. A display device comprising:
a substrate;
a pixel electrode and a common electrode spaced from each other on the substrate;
a light emitting element on the pixel electrode and the common electrode, and comprising a first contact electrode and a second contact electrode,
wherein the light emitting element further comprises:
a first element rod having a tapered shape, and comprising a first semiconductor layer doped with a first conductive dopant and an active layer; and
a second element rod on the first element rod and comprising a second semiconductor layer doped with a second conductive dopant and having a greater inclination angle than the first element rod.

2. The display device of claim 1, wherein a first inclination angle between an inner surface of the first element rod and one surface of the first semiconductor layer is in a range of 20° to 65°,
wherein a second inclination angle between an outer surface of the second element rod and an outer surface of the first element rod is in a range of 110° to 155°.

3. The display device of claim 1, wherein the first element rod has a width that becomes narrower toward the top on the substrate, and the second element rod has a same width at the top and bottom.

4. The display device of claim 1, wherein the second element rod further comprises an undoped semiconductor on the second semiconductor layer.

5. The display device of claim 4, wherein the undoped semiconductor has a light extraction pattern.

6. The display device of claim 1, further comprising an organic layer on a lower surface of the light emitting element on the pixel electrode and the common electrode; and
a first connection electrode connecting the pixel electrode and the first contact electrode and a second connection electrode connecting the common electrode and the second contact electrode.

7. The display device of claim 1, further comprising a first connection electrode between the first contact electrode and the pixel electrode, and a second connection electrode between the second contact electrode and the common electrode.

8. The display device of claim 1, wherein the light emitting element further comprises a conductive layer on a bottom surface of the first semiconductor layer,
wherein a protective layer around the conductive layer and the first semiconductor layer, the active layer, and the second semiconductor layer,
wherein the first contact electrode is on the protective layer and is connected to the conductive layer that is exposed and not covered by the protective layer,
wherein the second contact electrode is on the protective layer and is located in a hole penetrating the conductive layer, the first semiconductor layer, and the active layer.

9. The display device of claim 1, further comprising a partition wall around the light emitting element; and
a reflective layer on a side surface of the partition wall and at a space defined by the partition wall, the reflective layer being not in contact with the pixel electrode and the common electrode.

10. The display device of claim 9, further comprising a wavelength conversion layer at the space defined by the partition wall.

11. A display device comprising:
a substrate;
a pixel electrode on the substrate;
a light emitting element on the pixel electrode, and comprising a contact electrode; and
a common electrode on the light emitting element,
wherein the light emitting element further comprises:
a first element rod having a tapered shape, and comprising a first semiconductor layer doped with a first conductive dopant and an active layer; and
a second element rod on the first element rod, and comprising a second semiconductor layer doped with a second conductive dopant and having a greater inclination angle than the first element rod.

12. The display device of claim 11, wherein a first inclination angle between an inner surface of the first element rod and one surface of the first semiconductor layer is in a range of 20° to 65°, and
wherein a second inclination angle between an outer surface of the second element rod and an outer surface of the first element rod is in a range of 110° to 155°.

13. The display device of claim 11, wherein the first element rod has a width that becomes narrower toward the top on the substrate, and the second element rod has a same width at the top and bottom.

14. The display device of claim 11, further comprising an organic layer between the pixel electrode and the light emitting element; and
a connection electrode connecting the pixel electrode and the contact electrode.

15. The display device of claim 11, further comprising a connection electrode between the contact electrode and the pixel electrode.

16. The display device of claim 11, wherein the light emitting element further comprises:
a conductive layer on a bottom surface of the first semiconductor layer; and
a protective film on side surfaces of the conductive layer and side surfaces of the first semiconductor layer and the active layer,
wherein the contact electrode is on the protective film and is connected to the conductive layer exposed without being covered by the protective film.

17. A method for manufacturing a display device comprising:
forming a light emitting element; and
transferring the light emitting element onto a first substrate,
wherein the forming the light emitting element comprises:
forming an undoped semiconductor, a second semiconductor layer, an active layer, a first semiconductor layer, and a conductive layer on a second substrate;
forming a double mask on the first semiconductor layer and performing a first etching;
performing a second etching according to an etching method different from the first etching, and continuing the second etching until an inner surface of the first semiconductor layer and the active layer has a first inclination angle and an outer surface of the second semiconductor layer and an outer surface of the first semiconductor layer and the active layer have a second inclination angle;
forming a groove penetrating the conductive layer, the first semiconductor layer, and the active layer to expose the second semiconductor layer;
forming a protective layer around the conductive layer, the first semiconductor layer, the active layer, the second semiconductor layer, and the undoped semiconductor; and
forming a first contact electrode in contact with the conductive layer on the protective layer, and a second contact electrode in contact with the second semiconductor layer exposed by the groove.

18. The method of 17, wherein the first inclination angle is in a range of 20° to 65°, and
wherein the second inclination angle is in a range of 110° to 155°.

19. The method of 17, wherein the first etching is dry etching, and the second etching is wet etching.

20. An electronic device comprising:
a display device for displaying an image,
wherein the display device comprises:
a substrate;
a pixel electrode and a common electrode spaced from each other on the substrate;
a light emitting element on the pixel electrode and the common electrode, and comprising a first contact electrode and a second contact electrode,
wherein the light emitting element further comprises:
a first element rod having a tapered shape, and comprising a first semiconductor layer doped with a first conductive dopant and an active layer; and
a second element rod on the first element rod and comprising a second semiconductor layer doped with a second conductive dopant and having a greater inclination angle than the first element rod.
